(19) United States
(12) Patent Application Publication
(10) Pub. No.: US 2025/0023319 A1
(43) Pub. Date: Jan. 16, 2025

(54) LASER DEVICE AND LASER PROJECTION EQUIPMENT

(71) Applicant: HISENSE LASER DISPLAY CO., LTD., Shandong (CN)

(72) Inventors: Zinan Zhou, Shandong (CN); Yao LU, Shandong (CN); Zhaoshi GUO, Shandong (CN); Jianjun LI, Shandong (CN)

(21) Appl. No.: 18/902,481

(22) Filed: Sep. 30, 2024

Related U.S. Application Data
(63) Continuation of application No. PCT/CN2023/084222, filed on Mar. 28, 2023.

(30) Foreign Application Priority Data
Mar. 31, 2022 (CN) 202210344076.0
May 16, 2022 (CN) 20221173515.8

(51) Int. Cl. H01S 3/23; G03B 21/20; H01S 3/00; H01S 3/02; H01S 3/10; H01S 3/101

(52) U.S. Cl. CPC H01S 3/2391; G03B 21/2033; G03B 21/208; H01S 3/0071; H01S 3/025; H01S 3/10061; H01S 3/101

(57) ABSTRACT

A laser device and a laser projection equipment are provided. The laser device includes: at least one frame, each of the at least one frame including a substrate and an annular sidewall; a sealing light-transmitting layer, the substrate, the annular sidewall and the sealing light-transmitting layer forming a sealed accommodating space; a plurality of light emitting chips; at least one prism, configured to receive a laser beam exiting from a corresponding light emitting chip and to reflect the laser beam toward a light emitting direction of the laser device; and, a phase retarder, disposed within the accommodating space and parallel to the substrate, wherein a beam of at least a part of the light emitting chips passes through the phase retarder to change a polarization direction of a laser light before being transmit to the sealing light-transmitting layer

This application is a continuation application of PCT application No. PCT/CN2023/084222 filed on Mar. 28, 2023, which claims priority to Chinese patent application No. 202210344076.0 filed on Mar. 31, 2022 in the China National Intellectual Property Administration and entitled “LASER AND LASER PROJECTION APPARATUS” and Chinese patent application No. 202221173515.8 filed on May 16, 2022 in the China National Intellectual Property Administration and entitled “LASER”, the entire contents of all of which are incorporated herein by reference in their entirety.

### TECHNICAL FIELD

The present application relates to the field of optoelectronics technology, and in particular to a laser device and a laser projection equipment.

### BACKGROUND

At present, the laser projection industry is developing very rapidly, and the laser device, as one of the core components, plays an irreplaceable role. Semiconductor laser device is packaged after the chips are produced. Therefore, the packaging capability of the laser device has a very significant impact on the application, cost, performance and other indicators of the laser device.

Based on the development of laser devices and the demand for color displays, laser device packaging pursues the output of high-quality light beams in order to minimize the use of optical path components when applied to the optical path, minimizing and simplifying the size of laser display equipment.

### SUMMARY

Some embodiments of the present application disclose a laser device including:
at least one frame, each of the at least one frame including a substrate and an annular sidewall disposed on the substrate;
a sealing light-transmitting layer connected to the annular sidewall, the substrate, the annular sidewall and the sealing light-transmitting layer forming a sealed accommodating space;
a plurality of light emitting chips mounted on the substrate of the frame; the light emitting chips including at least one first type light emitting chip and at least one second type light emitting chip, a polarization direction of laser beam emitted from the first type light emitting chip being different from a polarization direction of laser beam emitted from the second type light emitting chip;
at least one prism, each of the at least one prism corresponding to at least one of the light emitting chips, each of the at least one prism being configured to receive a laser beam from a corresponding light emitting chip and to reflect the laser beam toward a light emitting direction of the laser device; and,
a phase retarder, disposed within the accommodating space and parallel to the substrate, wherein a laser beam from at least a part of the light emitting chips passes through the phase retarder to change a polarization direction before being transmit to the sealing light-transmitting layer.

Some embodiments of the present application also disclose a laser projection equipment including: a laser device described above;
a light valve modulation member, located on the light emitting side of the laser device, the light valve modulation member being configured to modulate the light from the laser device;
a projection lens, located on the light emitting side of the light valve modulation member.

### BRIEF DESCRIPTION OF DRAWINGS

In order to illustrate the technical solutions of the embodiments of the present application more clearly, the accompanying drawings to be used in the embodiments of the present application will be briefly described below, and it is obvious that the accompanying drawings described below are only some embodiments of the present application, and other accompanying drawings can be obtained according to these drawings for the people of ordinary skill in the field without creative labor.

FIG. 1 shows a schematic diagram of a structure of a laser device in related arts;

FIG. 2 shows a schematic diagram of a structure of a laser device provided by an embodiment of the present application;

FIG. 3 shows a side view schematic diagram I of a structure of a laser device shown in FIG. 2;

FIG. 4 shows a side view schematic diagram II of a structure of a laser device provided by an embodiment of the present application;

FIG. 5 shows a side view schematic diagram III of a structure of a laser device provided by an embodiment of the present application;

FIG. 6 shows a top view schematic diagram of a structure of the laser device shown in FIG. 5;

FIG. 7 shows a side view schematic diagram IV of a structure of a laser device provided by an embodiment of the present application;

FIG. 8 shows a top view schematic diagram of a structure of the laser device shown in FIG. 7;

FIG. 9 shows a top view schematic diagram III of a structure of a laser device provided by an embodiment of the present application;

FIG. 10 is a schematic diagram of a structure of a laser device provided by an embodiment of the present application;

FIG. 11 is a schematic diagram of the structure of another laser device provided by embodiments of the present application;

FIG. 12 is a schematic diagram of the structure of a further laser device provided by embodiments of the present application;

FIG. 13 is a schematic diagram of the structure of yet another laser device provided by embodiments of the present application;

FIG. 14 is a schematic diagram of a structure of a laser device provided in another embodiment of the present application;

FIG. 15 is a schematic diagram of the structure of another laser device provided in another embodiment of the present application;

FIG. 16 is a schematic diagram of the structure of yet another laser device provided by another embodiment of the present application;

FIG. 17 is a schematic diagram of the structure of yet another laser device provided by another embodiment of the present application;

FIG. 18 is a schematic diagram of the structure of a laser device provided in a further embodiment of the present application;

FIG. 19 is a schematic diagram of the structure of another laser device provided by a further embodiment of the present application;

FIG. 20 is a schematic diagram of the structure of a further laser device provided by a further embodiment of the present application;

FIG. 21 is a schematic diagram of the structure of yet another laser device provided by a further embodiment of the present application;

FIG. 22 is a schematic diagram of the structure of a laser device provided by yet another embodiment of the present application;

FIG. 23 is a schematic diagram of the structure of another laser device provided by yet another embodiment of the present application;

FIG. 24 is a schematic diagram of the structure of yet another laser device provided by yet another embodiment of the present application;

FIG. 25 is a schematic diagram of a structure of a laser projection equipment provided by an embodiment of the present application.

In the figures: 100—frame, 101—substrate, 102—annular sidewall, 107—bracket, 200—laser chip unit, 201—first type light emitting chip, 202—second type light emitting chip, L1—first type light emitting chip rows, L2—second type light emitting chip rows, 300—prism, S0—top surface, S1—first reflective surface, S2—second reflective surface, 400—phase retarder, 500—collimating lens, 600—sealing glass, 700—ceramic insulator, T1—first step surface, T2—second step surface, 10—laser device, 20—light valve modulation component, 30—projection lens.

### DETAILED DESCRIPTION

In order to make the foregoing purposes, features and advantages of the present application clearer and more understandable, the present application will be further described below in conjunction with the accompanying drawings and embodiments. However, the example embodiments are embodied in in a variety of forms and should not be construed as being limited to the embodiments set forth herein; rather, these embodiments are provided so that this disclosure will be thorough and complete, and will fully convey the concepts of the example embodiments to those skilled in the art. Identical accompanying symbols in the drawings denote the same or similar structures, and thus repetitive descriptions of them will be omitted. The words expressing position and orientation described in this application are illustrated by way of example in the accompanying drawings, but changes may be made as necessary, and the changes made are included in the scope of protection of this application. The accompanying drawings in this application are only configured to illustrate the relative positional relationship does not represent the true proportion.

With the development of the display industry, people put forward higher requirements for the color of the display. The current LED display technology due to its own limitations, it is difficult to have a purer color display and higher color gamut effect. Based on this, the laser display technology came into being, due to the inherent properties of the laser itself, it has a high brightness, wavelength singularity and other key indicators, so that it can achieve higher brightness under the better color reproduction and high color gamut, can achieve better display effects, to achieve a better viewing experience.

At present, laser technology is becoming increasingly mature, in which blue, red, green lasers in the visible light band have been mass-produced, so the development of three-color laser device has become a general trend. Based on the development of laser devices and the demand for color display, the current mainstream application of laser devices has been upgraded from monochrome laser to three-color laser. With the increase in laser device brightness, in order to minimize the size of the system, putting three-color laser package into a frame has become an inevitable trend, and has been widely used.

Due to the light emitting principles of lasers of different colors, the polarization direction of the laser beams emitted from the blue laser chip, the green laser chip, and the laser beam emitted from the red laser chip are different. Among them, the blue laser and the green laser have the same polarization direction, which is perpendicular to the red laser's polarization direction. This inconsistent polarization direction of lasers of different colors will cause some problems when used as a light source for lighting applications. For example, the more prominent point is that in the whole projection screen end, there will be a number of areas with different colors, “color block” or local color phenomenon, affecting the final viewing effect of the projected screen.

In order to improve this phenomenon, the current solution is to increase the number of system components that change the polarization state when designing the optical path system, so as to make the polarization direction of the three-color laser at the screen end consistent. However, this will inevitably lead to an increase in system costs, increase the complexity of the structure and unit process, and is not conducive to the miniaturization of the size of the entire equipment. FIG. 1 shows a schematic structure of a laser device in the related art.

As shown in FIG. 1, the laser device typically includes a frame 100, a plurality of light emitting chip units 200 disposed within the frame 100, and a prism 300 disposed on the light emitting side of the plurality of light emitting chip units 200.

Normally, a plurality of light emitting chip units 200 are provided within the frame 100, and a prism is provided on the light emitting side of each of the plurality of light emitting chip units 200 for reflecting light. A plurality of light emitting chip components 200 and the prism 300 on the light emitting side thereof form a unit, and the plurality of units are arranged in an array within the frame 100.

In the laser device of the multi-chip package structure, the plurality of light emitting chip units 200 include a red laser chip unit, a green laser chip unit, and a blue laser chip unit. Due to the inherent nature of the laser chip, the laser polarization direction of the red laser chip unit is usually the TM mode, while the laser polarization direction of the blue laser chip unit and the green laser chip unit is usually the TE mode, and the two are perpendicularly orthogonal, and based on the consideration of the optical efficiency of the optical system, it is common to refer to the polarization direction of the red laser, i.e, the TM mode of the laser device, as the second polarization direction of the light in the incident light plane of the screen at the end of the imaging screen, usually referred to as the P-light. The polarization direction of the red laser, i.e., the TM mode inside the laser, corresponds to the light in the second polarization direction of the screen incident light plane at the imaging screen end, which is usually referred to as the P light, while the polarization direction of the blue laser and the green laser corresponds to the light in the first polarization direction of the screen incident light plane at the imaging screen end, which is usually referred to as the S light. Even with the same optical lens and optical screen, there are differences in the refractive indices of the red laser and the blue and green lasers with different polarization directions, which leads to problems such as color spots, color blocks, and color deviation of the three-color lasers emitted from the laser device at the screen end after passing through the subsequent optical path.

In view of this, embodiments of the present application provide a laser device in which the polarization state of the laser beam emitted from the laser chip is adjusted at the time of packaging the laser device so that the laser beams emitted from the laser device all have the same polarization direction.

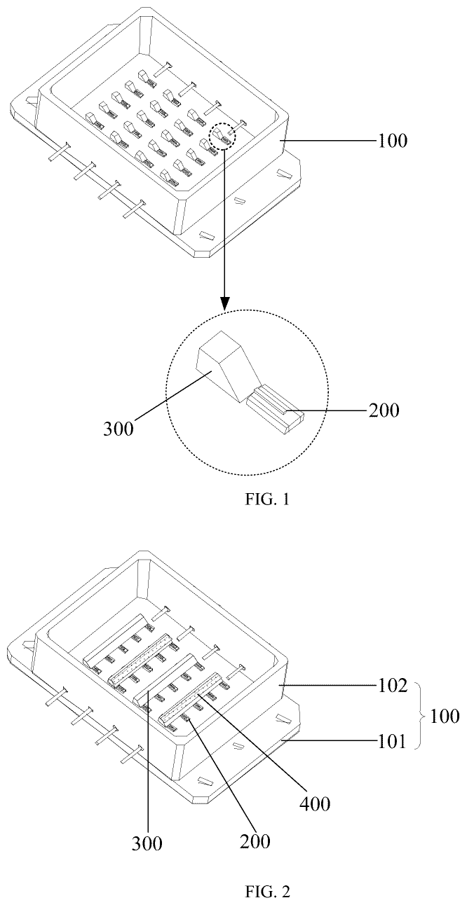

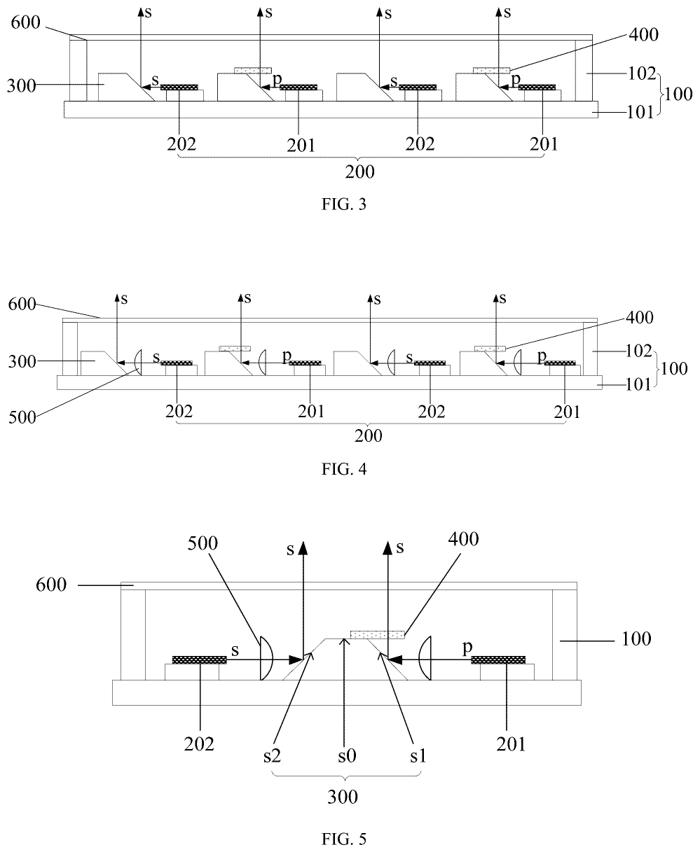

FIG. 2 shows a schematic structure of a laser device provided by an embodiment of the present application; and FIG. 3 shows a side view schematic structure of the laser device shown in FIG. 2. It is to be noted that the laser device described in embodiments of the present application refers to any kind of product, structure or component comprising at least one laser emitter, such as a complete laser system, a light-emitting module in the laser system, or a light-emitting unit in the light-emitting module.

As shown in FIGS. 2 and 3, the laser device includes: a frame 100, a plurality of light emitting chip units 200, a prism 300, and a phase retarder 400.

The frame 100 is configured to receive a plurality of light emitting chip units 200 and to encapsulate the plurality of light emitting chip units 200. The frame 100 includes a substrate 101 and an annular sidewall 102 disposed on the substrate, and the substrate 101 and the annular sidewall 102 form an accommodating space. Among them, the material of the frame 100 may be metal or ceramic, wherein the metal may be stainless steel and the ceramic may be aluminum oxide. The substrate 101 is preferably made of a metal with better heat dissipation performance, for example, oxygen-free copper may be used.

The plurality of light emitting chip units 200 are attached to the substrate 101 of the frame. In a particular implementation, the plurality of light emitting chip units 200 includes a laser chip and a heat sink. The laser chip and the heat sink are welded using a high precision eutectic welding machine to form the laser chip unit. The heat sink is configured to dissipate heat from the laser chip and can typically be fabricated using materials such as ALN, SiC in the first polarization direction, etc., and is not limited herein.

Embodiments of the present application provide a laser device having at least one prism 300 disposed in a receiving space of the frame 100 and, in particular, may be attached to a substrate 101 of the frame. A prism 300 may correspond to at least one of the plurality of light emitting chip units 200, specifically, the prism 300 is disposed on an output side of the corresponding plurality of light emitting chip units 200, and the prism 300 is configured to receive laser light emitted from the corresponding plurality of light emitting chip units 200 for reflection in the direction of light emitted from the laser device.

In particular embodiments, the prism 300 and the plurality of light emitting chip units 200 are temperature controlled between 200° C.-250° C. by means of sintered gold paste or sintered silver paste, etc., to achieve heat sinking and fixing of the prism relative to the frame.

The prism 300 may correspond one-to-one with each of the light emitting chips in the plurality of light emitting chip units 200 so as to have a plurality of prisms 300, or the prisms 300 may be provided to correspond to at least two light emitting chips.

In an embodiment of the present application, as shown in FIGS. 2 and 3, the plurality of light emitting chip units 200 include: a first type light emitting chip 201 and a second type light emitting chip 202, wherein a polarization direction of the laser beam emitted from the first type light emitting chip 201 is different from a polarization direction of the laser beam emitted from the second type light emitting chip 202.

In addition, the laser device of the present embodiment further comprises a sealing light-transmitting layer 600 connected to the annular sidewall 102; wherein the substrate 101, the annular sidewall 102, and the sealing light-transmitting layer 600 form a sealing accommodating space, and a plurality of the first type light emitting chips 201 and the second type light emitting chips 202 are disposed within the sealing accommodating space. Phase retarders which are parallel to the substrate 101 are also provided in the accommodating space, in particular, the phase retarders are half-wave chips. A light beam from at least a portion of the light emitting chips provided on the substrate 101 changes the polarization direction of the laser light via this phase retarder before being transmit to the sealing light transmitting layer 600 and finally being ejected from the laser device.

In some embodiments, the phase retarder chip is provided corresponding to one of the first type light emitting chip and the second type light emitting chip so as to change the polarization direction of one of the first type light emitting chip to make the polarization direction consistent with the polarization direction of the other type light emitting chip so as to achieve the same polarization direction of the three-color laser light emitted from the laser device.

And in some embodiments, the phase retarder chip may be adjusted for some of the first type light emitting chips and the second type light emitting chips. In particular, the phase retarder chip may be provided for some but not all of the first type light emitting chips, such that the phase retarder chip is a half-wave chip corresponding to the first type light emitting chip that changes the direction of polarization of the laser beam emitted from only a part of the first type light emitting chip, and in specific embodiments, the half-wave chip corresponding to half of the number of the first type light emitting chips is provided so as to change the direction of polarization of the laser beam emitted from only half of the first type light emitting chips, and the other half of the number of the first type light emitting chips is provided. In the specific implementation, the half-wave plate corresponds to half of the number of the first type light emitting chips, so that only half of the laser beams emitted from the first type light emitting chips are changed in the direction of polarization, and the laser beams emitted from the other half of the number of the first type light emitting chips do not pass through the half-wave plate, thereby maintaining the original direction of polarization. In the above arrangement, there are two different polarization directions for the first type light emitting chip, and the degree of difference between the polarization directions of the second type light emitting chip and the second type light emitting chip is reduced, and it is also advantageous to reduce the degree of coherence of the laser beams of the same type light emitting chip having two different polarization directions.

Furthermore, the phase retardation chips may also correspond to a portion of the first type light emitting chips and a portion of the second type light emitting chips, respectively, and are also specifically selected to be both 50%, wherein, among the plurality of first type light emitting chips and the plurality of second type light emitting chips, the polarization direction of half of the laser beams of each of the plurality of first type light emitting chips and the polarization direction of the laser beams of each of the plurality of second type light emitting chips is changed, and the polarization direction of the laser beams of the plurality of second type light emitting chips of each of the plurality of second type light emitting chips is maintained in the original polarization direction. As a result, the first type light emitting chip and the second type light emitting chip have two different polarization directions, and the degree of difference in the polarization directions is improved, and the laser beams having two different polarization directions for the same type of light emitting chip also contribute to a reduction in the degree of coherence.

The following examples are illustrated when the phase retarder is provided in the optical path of a laser beam in one of the polarization directions, and the same can be seen in the following example when the phase retarder is provided partially according to a certain type of light emitting chip.

Taking FIG. 3 as an example, in this embodiment of the present application, the reflecting prism 300 is provided with at least one phase retarder 400, and the phase retarder 400 may be provided on the prism on the light emitting side of the first type light emitting chip 201 or the second type light emitting chip 202; the phase retarder 400 is configured to receive the reflected laser light from the corresponding prism 300 and to change the direction of polarization of the laser light emitted from the corresponding second type light emitting chip so that the laser beam emitted from the laser device has the same direction of polarization.

In a specific implementation, the top surface of the prism 300 is usually a flat surface, so that the phase retarder 400 can be provided at an edge of this top surface and extend a certain distance toward the reflecting surface of the prism, so that the laser light emitted from the laser chip unit can be reflected by the prism 300 and then be incident on the phase retarder 400.

Since the plurality of light emitting chip components 200 and the prism 300 are usually attached to the frame 100 by means of a sintered gold paste or a sintered silver paste, a gold-plated layer can be provided on the surface of the phase retarder 400 that is in contact with the prism 300, so that the phase retarder 400 can be attached to the prism 300 by the same process. In addition, the phase retarder may also be affixed to the prism using an organic-free, high temperature resistant adhesive, which is not limited herein.

The phase retarder 400 only needs to be provided on top of the prism on the light output side of one of the first type light emitting chip 201 and the second type light emitting chip 202 so that the polarization direction of the laser beam emitted from one type of laser emitting chip is the same as that of the laser beam emitted from the other type of laser emitting chip, thereby avoiding color problems due to the difference in polarization states. This avoids the color problem caused by the different polarization states.

In practice, the laser apparatus usually includes a red laser chip unit, a green laser chip unit and a blue laser chip unit, wherein the red laser light emitted from the red laser chip unit is orthogonal to the green laser light emitted from the green laser chip unit and the blue laser light emitted from the blue laser chip unit in the direction of polarization. Then, in the embodiment of the present application, the first type light emitting chip 201 may include a red laser chip unit, and the second type light emitting chip 202 may include a green laser chip unit and a blue laser chip unit; or the first type light emitting chip 201 may include a green laser chip unit and a blue laser chip unit, and the second type light emitting chip 202 may include a red laser chip unit, and is not limited herein.

Since the polarization directions of the red laser and the blue laser and the green laser are perpendicular to each other, the phase retarder 400 can be used as a half-wave plate to maintain a uniform polarization direction.

The laser apparatus shown in FIG. 3 is illustrated as an example, wherein the first type light emitting chip 201 is a red laser chip unit, and the second type light emitting chip 202 includes a green laser chip unit and a blue laser chip unit. Then, the first type light emitting chip 201, i.e., the prism on the light emitting side of the red laser chip unit, can be provided with a half-wave plate so as to convert the light in the second polarization direction emitted from the red laser chip unit into the light in the first polarization direction which is consistent with the polarization direction of the light in the first polarization direction emitted from the green laser chip unit and the blue laser chip unit.

Of course, it is also possible to provide a half-wave plate on a prism on the light emitting side of the second type light emitting chip 202, i.e., the green laser chip unit and the blue laser chip unit, so as to convert the light emitted in the first polarization direction from the green laser chip unit and the blue laser chip unit into the light in the second polarization direction so as to maintain the same polarization direction as that of the light in the second polarization direction emitted from the red laser chip unit.

In the specific implementation process, a phase retarder chip may be placed on the prism on the light emitting side of which laser chip unit is placed according to the layout of the red laser chip unit, the green laser chip unit and the blue laser chip unit, which is based on the principle of a simplified and easy-to-assemble structure and is not limited herein.

FIG. 4 shows a side view schematic structure II of a laser apparatus provided by an embodiment of the present application.

As shown in FIG. 4, the laser device further comprises: a collimating lens 500; and a scaling glass 600.

The collimating lens 500 is disposed within the accommodating space formed by the frame 100, and in particular may be fixed to the substrate 101 of the frame. In an embodiment of the present application, a collimating lens 500 corresponds to a plurality of light emitting chip units 200, and the collimating lens 500 is disposed between the corresponding plurality of light emitting chip units 200 and the corresponding prism 300. The collimating lens is configured to collimate the laser light emitted from the plurality of light emitting chip units 200 so that the effect of different angles of incidence on the phase retarder need not be considered when adjusting the phase retarder, thereby simplifying the design.

In a specific implementation, the collimating lens 500 may be a single lens or a group of lenses, and in particular may be an aspherical lens, a column lens, a free-form surface lens, or a Fresnel lens, without limitation herein. In addition, the reflecting surface of the prism 300 may also be set as a curved surface to simultaneously play the role of reflecting the light and collimating the light, in which case the reflecting surface of the prism 300 preferably adopts an aspherical curved surface, and is not limited herein.

The sealing glass 600 is disposed in an open position over the frame 100, and the sealing glass 600 is welded to the edges of the frame 100, thereby encapsulating the laser device. In particular, the scaling glass 600 may be made of sapphire, quartz, Bk7, or the like. The frame 100 and the sealing glass 600 may be welded together by resistance welding or direct welding in the first polarization direction of Au. In the resistance welding method, the sealing glass 600 is welded to the metal by low-temperature glass adhesive prior to resistance welding.

The laser chip components in the laser device provided in the embodiments of the present application can be arranged using a variety of arrangement rules, and accordingly, the prism 300 can be deformed and designed, together with the phase retarder chip set at a reasonable position, to realize the purpose of the laser beam emitted from the laser device having the same polarization direction.

In some embodiments, as shown in FIG. 1, the plurality of light emitting chip units 200 and the prisms 300 may still adopt a one-to-one corresponding setting relationship, and a phase retarder chip may be provided on the prisms on the light emitting side of each first type light emitting chip; or a phase retarder chip may be provided on the prisms on the light emitting side of each second type light emitting chip. This setting method does not need to take into account the arrangement rules of the different types of laser chip units, and it is only necessary to set the phase retarder on the prisms on the light emitting side of the laser chip units that are required to perform the polarization state conversion.

n some embodiments, as shown in FIG. 1, each laser chip unit is arranged in a plurality of rows along a predetermined direction, and in the structure shown in FIG. 1, for example, the laser device usually includes two rows of red laser chip units, one row of green laser chip units, and one row of blue laser chip units, and the rows of red laser chip units are arranged in an interchangeable arrangement with the rows of green laser chip units and the rows of blue laser chip units. In this case, it is possible to change the polarization direction of the laser beams emitted from the two rows of red laser chip units, or it is also possible to change the polarization direction of the laser beams emitted from one row of green laser chips and one row of blue laser chips. At this time, one phase retarder chip can be placed on each prism on the light side of the two rows of red laser chip units; alternatively, one phase retarder chip can be placed on each prism on the light side of the rows of green laser chip units, and one phase retarder chip can be placed on each prism on the light side of the rows of blue laser chip units. This can reduce the number of phase retarder chips set, increase the size of the phase retarder chips, and is conducive to increasing the stability between the phase retarder chips and the prisms.

In some embodiments, as shown in FIG. 2, each laser chip unit is arranged in a plurality of rows along a predetermined direction, and thus the prisms 300 may also be provided as strip prisms extending along the direction of the rows of the laser chip units, such that one prism 300 corresponds to at least one row of the plurality of light emitting chip units 200, which may reduce the number of prisms.

Taking the structure shown in FIG. 2 as an example, the first type light emitting chip 201 is a red laser chip unit, and the second type light emitting chip 202 is a green laser chip unit and a blue laser chip unit; or the first type light emitting chip 201 is a green laser chip unit and a blue laser chip unit, and the second type light emitting chip 202 is a red laser chip unit. The two first type light emitting chip rows and the two second type light emitting chip rows are arranged in an interchangeable arrangement, and a bar prism is provided on the light emitting side of each laser chip unit row. A stripe phase emitting chip is provided on the stripe prism on the light emitting side of each first type light emitting chip row; alternatively, a stripe phase retarder is provided on the stripe prism on the light emitting side of the first second type light emitting chip row to make the polarization states of the lasers finally emitted from the two types of laser chip units the same.

In adopting the structure shown in FIG. 1 or FIG. 2, each row of laser chip units is connected in series with each other, and a pin is provided on the annular side wall 102 of the frame on each side of each row of laser chip units for connecting the laser chip units of the corresponding rows, and one of the pins on each side applies a positive signal and the other applies a negative signal so as to drive a laser light to be emitted from the laser chip units of the row.

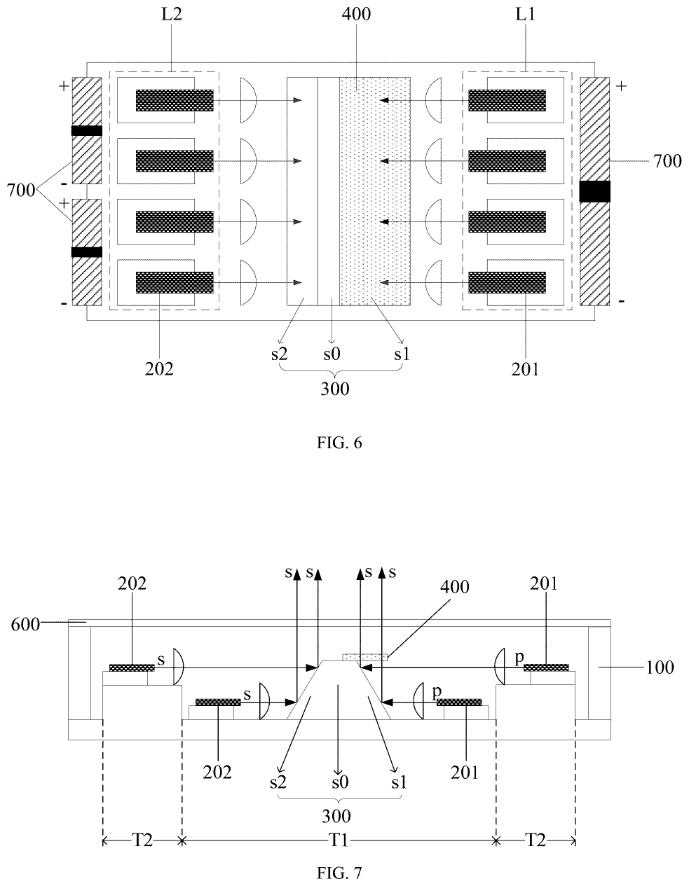

FIG. 5 shows a side view schematic structure of a laser device provided by an embodiment of the present application III; and FIG. 6 shows a top view schematic structure of the laser device shown in FIG. 5.

In some embodiments, as shown in FIGS. 5 and 6, each of the first type light emitting chips 201 in the laser device is arranged in a first type light emitting chip row L1; each of the second type light emitting chips 202 is arranged in a second type light emitting chip row L2. For example, the first type light-emitting chip row L1 includes red laser chip components only, and the second type light-emitting chip row L2 includes green laser chip components and blue laser chip components only; or, the first type light emitting chip row L1 includes a green laser chip component and a blue laser chip component, and the second type light emitting chip row L2 includes only a red laser chip component.

The prism 300 includes a top surface in a first polarization direction of 0, and a first reflective surface in a first polarization direction of 1 and a second reflective surface in a first polarization direction of 2 symmetrically disposed with respect to the top surface, wherein a first type light emitting chip row L1 is disposed on the side of the first reflective surface in the first polarization direction of 1 of the prism, wherein the first reflection surface in the first polarization direction of 1 is configured to receive the laser beam emitted from the first type light emitting chips in each of the first type light emitting chip rows L1 201 emitting laser light to be reflected in the light-out direction of the laser device; the second type light emitting chip row L2 is disposed on the first polarization direction of 2 side of the second reflecting surface of the prism, and the second polarization direction of 2 of the first polarization direction of the second reflecting surface is configured to receive the laser light emitted from the second type light emitting chips 202 in each of the second type light emitting chip rows L2 to be reflected in the light-out direction of the laser device.

Since the laser chip units emitting laser light in the same polarization direction are arranged in a row, the phase retarder 400 may be provided at the edge of the first polarization direction 0 of the top surface of the prism near the first polarization direction 1 of the first reflecting surface; alternatively, the phase retarder 400 may be provided at the edge of the first polarization direction 0 of the top surface of the prism near the first polarization direction 2 of the second reflecting surface, so that the two types of laser chips have the same polarization direction of the final emitted laser beams. The laser beams finally emitted from the two laser chip units are polarized in the same direction.

In adopting the laser apparatus structure shown in FIG. 5, only one prism 300 needs to be provided, and by providing both opposite surfaces of the prism as reflecting surfaces, the laser light emitted from both rows of laser chip units can be reflected simultaneously.

In a specific implementation, the width of the 0 in the first polarization direction of the top surface of the prism 300 is greater than or equal to 4 mm so that there is a sufficient taping distance between the phase retarder 400 and the 0 in the first polarization direction of the top surface. The height of the prism 300 is usually greater than 4 mm, and the specific dimensions may be designed according to the optical path.

When the laser chip unit included in the first type light emitting chip row L1 is a red laser chip unit and the laser chip unit included in the second type light emitting chip row L2 is a green laser chip unit and a blue laser chip unit, as shown in FIG. 6, the laser apparatus is also provided with ceramic insulators 700 on the side walls of the frame. Three ceramic insulators may be provided for the three colors of the laser chip units. Among them, the red laser chip units are connected in series with each other, and one of the two red laser chip units located on both sides is connected to the positive end of the corresponding ceramic insulator 700, and the other is connected to the negative end of the corresponding ceramic insulator 700. The green laser chip units are provided adjacent to each other, and the green laser chip units are connected in series with each other, and one of the two green laser chip units located on both sides is connected to the positive terminal end of the corresponding ceramic insulator 700, and the other is connected to the negative terminal end of the ceramic insulator 700. The blue laser chip units are provided adjacent to each other, and the blue laser chip units are connected in series with each other, and one of the two blue laser chip units located on both sides is connected to the positive terminal end of the corresponding ceramic insulator 700, and the other is connected to the negative terminal end of the ceramic insulator 700. The laser chip units and the ceramic insulators may be connected with gold wires, and the diameter and number of the gold wires may be selected according to the current of the laser apparatus. With the connection relationship described above, an electrical signal may be applied to the positive and negative poles of the ceramic insulator to drive the connected laser chip unit to emit laser light.

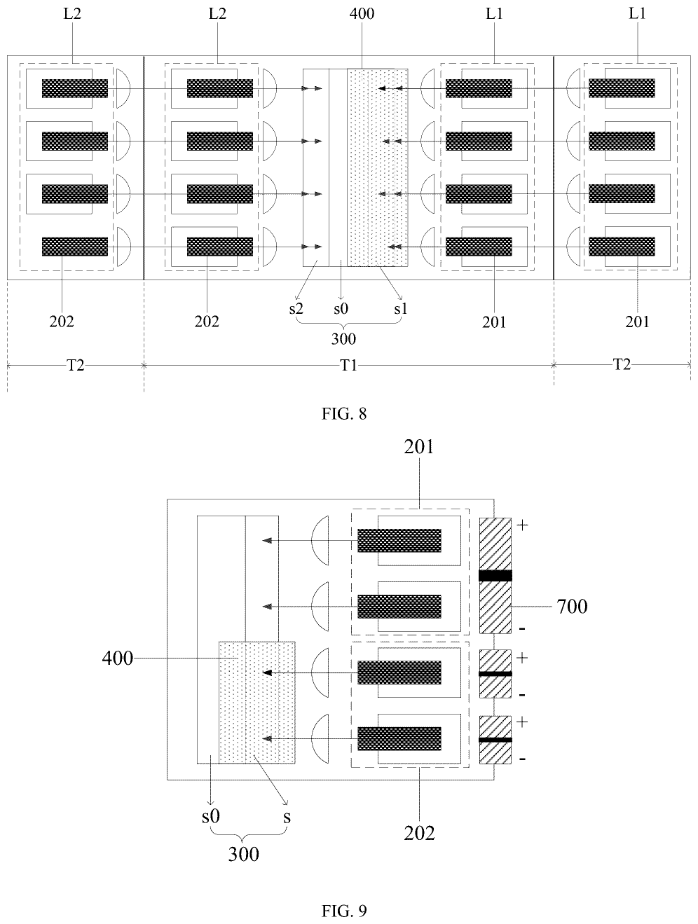

FIG. 7 shows a side view schematic structure of a laser device provided by an embodiment of the present application IV; and FIG. 8 shows a top view schematic structure of the laser device shown in FIG. 7.

In some embodiments, as shown in FIGS. 7 and 8, each of the first type light emitting chips 201 in the laser device is arranged in two first type light emitting chip rows L1; each of the second type light emitting chips 202 is arranged in two second type light emitting chip rows L2. For example, one of the two first type light emitting chip rows L1 contains only a red laser chip unit, one of the two second type light emitting chip rows L2 contains a green laser chip unit, the other contains a blue laser chip unit, and the other contains a blue laser chip unit; or one of the two first type light emitting chip rows L1 contains a green laser chip unit, the other contains a blue laser chip unit, and the two second type light emitting chip rows L2 contain only a red laser chip unit.

For sharing a prism 300, as shown in FIG. 7, the substrate of the frame 100 has a stepped structure, and the substrate of the frame includes a first-stage stepped surface T1 and a second-stage stepped surface T2 disposed on both sides of the first-stage stepped surface, respectively; and the height of the second-stage stepped surface T2 is greater than the height of the first-stage stepped surface T1.

The prism 300 includes: a top surface having a first polarization direction of 0, and a first reflection surface having a first polarization direction of 1, and a second reflection surface having a first polarization direction of 2 symmetrically disposed with respect to the top surface having a first polarization direction of 0.

The prism 300 is disposed on the first step surface T1, and the two first type light emitting chip rows L1 are both disposed on one side of the first polarization direction 1 of the first reflective surface of the prism, wherein one of the first type light emitting chip rows L1 is disposed on the first step surface T1 and the other of the first type light emitting chip rows is disposed on the second step surface T2; the first polarization direction 1 of the first reflecting surface is configured to receive the laser beam emitted from each of the first type light emitting chips 201 in the first type light emitting chip L1 so as to be reflected in the outgoing direction of the laser. in which the laser light emitted from each of the first type light emitting chips 201 is reflected in the direction of light emission from the laser device.

Both of the two second type light emitting chip rows L2 are disposed on one side of the 2 of the first polarization direction of the second reflecting surface of the prism, wherein one of the second type light emitting chip rows L2 is disposed on the first step surface T1 and the other of the second type light emitting chip rows L2 is disposed on the second step surface T2; the 2 of the first polarization direction of the second reflecting surface is configured to receive the second type light emitting chip 202 ejected from the respective second type light emitting chip 202 of the two second type light emitting chip rows L2 for laser light to be reflected in the outgoing direction of the laser device.

The laser chip units in which the outgoing laser light is in the same polarization direction are disposed on the same side of the prism, and thus the phase retarder 400 may be disposed at an edge of the 0 of the first polarization direction of the top surface of the prism near the 1 of the first polarization direction of the first reflecting surface; alternatively, the phase retarder 400 may also be disposed at an edge of the 0 of the first polarization direction of the top surface of the prism near the 2 of the first polarization direction of the second reflecting surface.

In adopting the laser apparatus structure shown in FIG. 7, only one prism 300 needs to be provided, and both rows of laser chip units located on the same side of the prism 300 emit light toward a reflecting surface on that side of the prism. In order to avoid blocking the laser light emitted from the rear row of laser chip units which is further away from the prism, the embodiment of the present application sets the substrate of the frame into a stepped structure so that the front row of laser chip units which is closer to the prism can be set together with the prism on a first step surface, and the rear row of laser chip units which is further away from the prism can be set on a second step surface which is at a higher height.

Since each side of the reflecting surface of the prism must receive the laser light emitted from two rows of laser chip units, the size of the prism shown in FIG. 7 is relatively large compared to the prism shown in FIG. 5, and the specific size can be selected according to the optical path, which is not limited here.

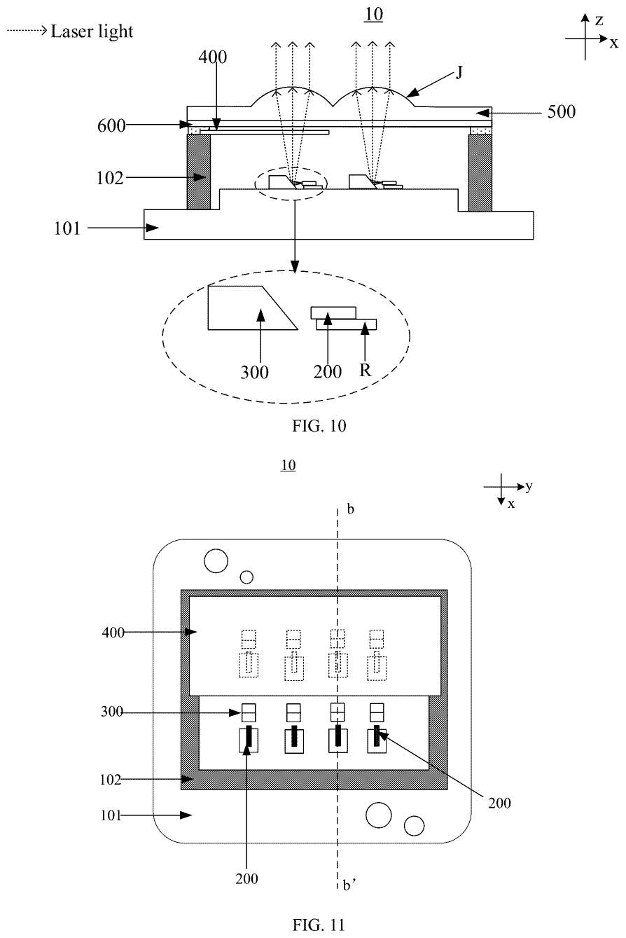

FIG. 9 is a schematic diagram of a top view structure of a laser device provided by an embodiment of the present application III.

In some embodiments, both the first type light emitting chip 201 and the second type light emitting chip 202 are included in at least one of the respective laser chip unit rows as shown in FIG. 9. At this time, the phase retarder 400 no longer covers the entire surface of the prism, but is provided on an area of the prism corresponding to the first type light emitting chip 201 or an area corresponding to the second type light emitting chip 202.

Taking the structure shown in FIG. 9 as an example, each laser chip unit is arranged to form a laser chip unit row, wherein the first type light emitting chip 201 includes a red laser chip unit and the second type light emitting chip 202 includes a green laser chip unit and a blue laser chip unit. Laser chip units having the same polarization direction of the emitted laser light are provided adjacent to each other.

The prism 300 includes a top surface having a first polarization direction of 0 and a reflection surface having a first polarization direction of, and the phase retarder is provided on a surface of the prism on the light emitting side of the second type light emitting chip 202.

The laser device may include three ceramic insulators 700, wherein the red laser chip units are provided adjacent to each other and the red laser chip units are connected in series with each other, and one of the two red laser chip units disposed on each side connects the positive end of the corresponding ceramic insulator 700 and the other connects the negative end of the corresponding ceramic insulator 700. The green laser chip units are provided adjacent to each other, and the green laser chip units are connected in series with each other, and one of the two green laser chip units disposed on both sides is connected to the positive terminal end of the corresponding ceramic insulator 700, and the other is connected to the negative terminal end of the ceramic insulator 700. The blue laser chip units are provided adjacent to each other, and the blue laser chip units are connected in series with each other, and one of the two blue laser chip units located on both sides is connected to the positive terminal end of the corresponding ceramic insulator 700, and the other is connected to the negative terminal end of the ceramic insulator 700. The laser chip units and the ceramic insulators may be connected with gold wires, and the diameter and number of the gold wires may be selected according to the current of the laser apparatus. With the connection relationship described above, an electrical signal may be applied to the positive and negative poles of the ceramic insulator to drive the connected laser chip unit to emit laser light.

FIG. 9 is illustrated by way of example with only one row of laser chip units, and in specific implementations, the laser device may be provided with two rows of laser chip units as shown in FIG. 9 so that the prism is set up as a symmetrical structure as shown in FIG. 5; or it may also include more than two rows of laser chip units, wherein each row of laser chip units is designed by adopting the same design ideas as those in FIG. 9 and is not limited thereto.

FIG. 10 is a schematic diagram of a structure of a laser device provided by an embodiment of the present application. The laser device 10 may include a substrate 101, a tubular sidewall 102, a plurality of light emitting chip units 200, a plurality of reflecting prisms 300, and a scaling light transmitting layer 600 enclosing the substrate 101 and the sidewall 102 to form a sealing receiving space. In contrast to the previous embodiment, the phase retardation chips 400 are disposed away from the substrate 101, the light emitting chips 200, and the reflecting prisms 300, and in particular may be secured by means of a bracket or by connection to a sidewall of the frame.

In an embodiment of the present application, the material of the sidewall 102 may include a ceramic, such as aluminum trioxide (chemical formula: Al2O3). In a particular implementation, the phase retarder 400 may be fixed to the sidewall 102, and the sealing light transmissive layer 600 may also be fixed to the sidewall 102. Because the ceramic material is easier to fix or combine with the phase retarder 400 and the sealing light-transmitting layer 600, the laser device 10 provided by the embodiments of the present application has more processing advantages compared to the lasers with metal sidewalls in the related technology, and the fixation strength of the phase retarder 400 and the scaling light-transmitting layer 600 with the sidewall 102 can be guaranteed to ensure that the laser device 10 has higher reliability.

In this example, each reflective prism 300 may correspond to at least one light emitting chip 200, with different reflective prisms 300 corresponding to different light emitting chips 200, and the laser light emitted from each light emitting chip 200 may be directed to a reflective surface of the corresponding reflective prism 300, which may reflect the incoming laser light along the direction away from the substrate 101 (e.g., the z-direction in FIG. 10). In a particular embodiment, a surface in the reflective prism 300 opposite the light emitting chip 200 may be coated with a reflective film to form this reflective surface.

Similarly, in this example, the plurality of light emitting chip units 200 in the laser device 10 may include a first type light emitting chip and a second type light emitting chip, wherein the direction of polarization of the laser light emitted from the first type light emitting chip is perpendicular to the direction of polarization of the laser light emitted from the second type light emitting chip. The color of the laser light emitted from the first type light emitting chip and the laser light emitted from the second type light emitting chip is also different. In a specific embodiment, the laser light emitted from the first type light emitting chip is polarized light in the first polarization direction, and the laser light emitted from the second type light emitting chip is polarized light in the second polarization direction. For example, the polarized light in the first polarization direction may include green laser light and blue laser light, and the polarized light in the second polarization direction may include red laser light. In a specific embodiment, it is also possible that the laser light emitted from the first type light emitting chip is polarized light in the second polarization direction, and the laser light emitted from the second type light emitting chip is polarized light in the first polarization direction.

There may be a plurality of first type light emitting chips and a plurality of second type light emitting chips in the laser device 10. Exemplarily, some of the first type light emitting chips of the plurality of first type light emitting chips are green light chips for emitting a green laser light, and the remaining part of the first type light emitting chips are blue light chips for emitting a blue laser light. The plurality of second type light emitting chips are red light emitting chips for emitting red laser light. Or the plurality of first type light emitting chips may all emit green laser light or all emit blue laser light, and the embodiments of the present application are not limited. In a particular embodiment, the laser device 10 may also have the plurality of first type light emitting chips which are all red chips and the plurality of second type light emitting chips which include a plurality of green chips and a plurality of blue chips, and the embodiments of the present application are not limited.

The positive projection of the phase retarder 400 on the substrate 101 may cover the plurality of first type light emitting chips and their corresponding reflective prisms 300, and the positive projection may be located outside the plurality of second type light emitting chips and their corresponding reflective prisms 300. In this way, the laser light emitted from the first type light emitting chip after being reflected by the corresponding reflecting prisms 300 may be directed to the phase retarder 400, and the phase retarder 400 may rotate the direction of polarization of the incoming laser light by 90 degrees, whereby the laser light emitted from the first type light emitting chip may be in the same direction as the direction of polarization of the laser light emitted from the second type light emitting chip after passing through the phase retarder 400.

In the laser device provided in an embodiment of the present application, a phase retarder chip is provided on a side of the light emitting chip away from the substrate, and a positive projection of the phase retarder chip on the substrate covers each of the first type light emitting chip and the corresponding reflecting prisms in the laser device and is located outside of each of the second type light emitting chip and the corresponding reflecting prisms in the laser device. In this way, the laser light emitted from the first type light emitting chip can be reflected on the corresponding reflecting prisms and then emitted after the phase retarder rotates the adjusted polarization direction by 90 degrees, while the polarization direction of the laser light emitted from the second type light emitting chip does not change. The laser light emitted from the first type light emitting chip is polarized in the same direction as the laser light emitted from the second type light emitting chip after the phase retarder, and the laser light emitted from the laser apparatus has the same polarization direction. Therefore, the laser emitted from the laser device originating from different types of light emitting chips has a smaller difference in transmissive-reflective properties when transmitted in the subsequent optical components, and the laser emitted from the laser device has a smaller change in the ratio of the various colors of the laser light after passing through the subsequent optical components, so as to attenuate the color deviation of the projection image formed by the laser light and improve the display effect of the projection image.

FIG. 11 is a schematic diagram of the structure of another laser device provided by embodiments of the present application, FIG. 11 may be a top view of FIG. 10, FIG. 10 may be a schematic diagram of a cross-section b-b′ of the laser device shown in FIG. 11, and FIG. 11 does not illustrate the phase retarder 400 and the light-transmitting sealing layer 600 in the laser device 10. With further reference to FIGS. 10 and 13, the laser device 10 may also include a plurality of heat sinks R. The plurality of heat sinks R corresponds to a plurality of light emitting chip units 200 in the laser device 10. The heat sinks R are in contact with the substrate 101 and are attached to the substrate 101, and each light emitting chip 200 is attached to the corresponding heat sink R. In a particular embodiment, both the heat sink R and the reflective prism 300 may be attached to the substrate 101 by silver adhesive sintering.

As shown in FIG. 11, the plurality of light emitting chip units 200 in the laser device 10 may be arranged in multiple rows and columns, and FIG. 11 takes an example of the laser device 10 including eight light emitting chips 200 arranged in two rows and four columns, where the row direction is the y direction and the column direction is the x direction. The number and arrangement of the light emitting chips 200 in the laser device 10 may also be adapted, such that the laser device 10 may also include 10 light emitting chips 200 arranged in two rows and five columns, or 15 light emitting chips 200 arranged in three rows and five columns, and the embodiments of the present application are not limited. In a specific embodiment, the spacing of adjacent light emitting chips 200 may be from 1 mm to 3.5 mm.

In a specific implementation, as shown in FIGS. 10 and 3, a plurality of first type light emitting chips and a plurality of second type light emitting chips in the laser device 10 may be arranged in two separate areas, and the arranged area of the plurality of first type light emitting chips and the arranged area of the plurality of second type light emitting chips may be lined up along a target direction. When the target direction is the x direction, the x direction is perpendicular to the y direction. When the laser device 10 includes two rows of light emitting chips 200, one row is a first type light emitting chip and the other row is a second type light emitting chip. When the first row in the y-direction in FIG. 11 is a first type light emitting chip and the second row is a second type light emitting chip. In a specific embodiment, this target direction may also be the y-direction, such that half of each row of light emitting chips is the first type light emitting chip and the other half is the second type light emitting chip. The number of the first type light emitting chips and the number of the second type light emitting chips may or may not be the same, and the embodiments of this application are not limited.

In a particular implementation, the first type light emitting chips and the second type light emitting chips may also not be provided in two separate areas, and the first type light emitting chips and the second type light emitting chips may be staggered. For example, the first type light emitting chip and the second type light emitting chip may be included in each row of light emitting chips of the laser device 10, and for example, the first type light emitting chip and the second type light emitting chip may be provided alternately one by one in each row.

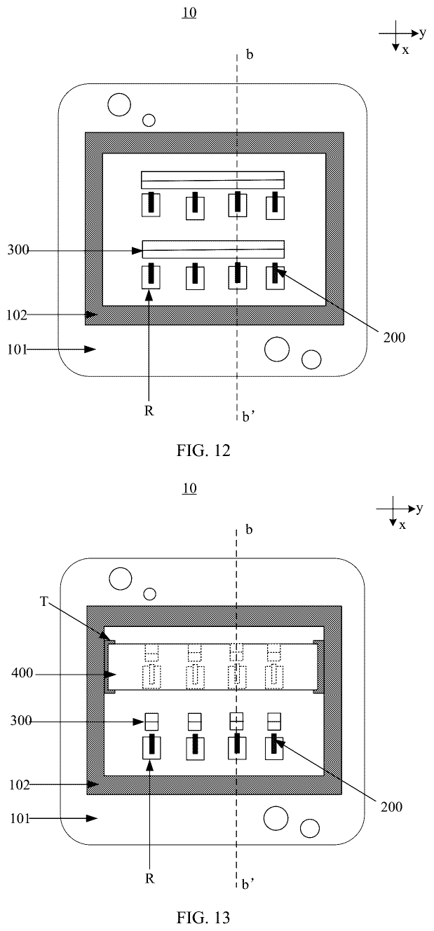

In a specific implementation, FIG. 11 is illustrated with a plurality of reflecting prisms 300 in the laser device 10 corresponding to a plurality of light emitting chip units 200 one by one, each reflecting prism 300 corresponding to a light emitting chip 200. In a particular implementation, one reflective prism 300 may also correspond to a plurality of light emitting chip units 200. As an example, FIG. 12 is a schematic diagram of the structure of another laser device provided by an embodiment of the present application. As shown in FIG. 12, each reflective prism 300 may correspond to a row of light emitting chips. When the laser device 10 includes two rows of light emitting chips 200, each row of light emitting chips 200 having the same direction of light emission, the laser device 10 may include only two reflective prisms 300, wherein each reflective prism 300 may be in the form of a strip, the direction of extension of the reflective prisms being parallel to the direction of the row of light emitting chips 200 corresponding to the row of light emitting chips 200. In a particular implementation, each reflective prism 300 may also correspond to only a portion of the light emitting chips in the row of light emitting chips 200. For example, each reflecting prism 300 may correspond to only two light emitting chips 200, and each row of light emitting chips 200 may correspond to two reflecting prisms 300.

In this application embodiment, the phase retarder piece 400 in the laser device 10 may be optionally provided in a variety of ways. For example, the phase retarder piece 400 may be attached directly to the sidewall 102 and supported by the sidewall 102. Or, the laser device 10 may also include a bracket that may be surrounded by the sidewall 102, and the phase retarder layer 400 is supported by the bracket. Or the phase retardation layer 400 may be supported by both the bracket and the sidewall, such that an edge of the phase retardation layer 400 is attached to a side of the bracket away from the substrate 101, and the phase retardation layer 400 is also attached to the sidewall 102. Several optional ways of setting the phase retarder are described below in conjunction with the accompanying drawings.

In a first optional configuration, the laser device 10 may include only one phase retarder 400, wherein the phase retarder 400 is fixed to the sidewall 102 and supported only by the sidewall 102. The phase retarder 400 may be rectangular in shape. The sidewall 102 may be surrounded by a plurality of subwalls. If the sidewall 102 is in the form of a square tube and the front projection of the sidewall 102 on the substrate 101 is substantially rectangular, the sidewall 102 may be enclosed by four subwalls.

In one example, the phase retarder piece 400 may be disposed on a side of the sidewall 102 away from the substrate 101. At least two opposite edges of the phase retarder piece 400 are attached to a surface of the sidewall 102 away from the substrate 101. As shown in FIGS. 10 and 11, three edges of the phase retarder piece 400 are fixed to the surface of the sidewall 102 away from the substrate 101. The three edges of the phase retarder piece 400 are attached to the surfaces of the three subwalls of the sidewall 102 away from the substrate 101, as shown. In a specific implementation, each edge of the phase retarder layer 400 may cover only a portion of an area in one of the three subwalls of the sidewall 102. In a specific implementation, the sidewall 102 may have other shapes, in which case the number of subwalls included in the sidewall 102 may vary accordingly. If the front projection of the sidewall 102 on the substrate 101 is substantially pentagonal, the sidewall 102 is surrounded by five subwalls, the embodiments of the present application are not limited.

An edge of the light-transmitting sealing layer 600 may be attached to a surface of the sidewall 102 away from the substrate 101. For the three subwalls in the sidewall 102 covered by the phase retardation layer 400, the light-transmitting sealing layer 600 may be fixed by an adhesive to the portions of the three subwalls not covered by the light-transmitting sealing layer 600; the edges of the light-transmitting sealing layer 600 may also be fixed to the three edges of the side of the phase retardation layer 400 away from the substrate. For a subwall in the sidewall 102 that is not covered by the phase retarder 400, the light-transmitting sealing layer 600 may be attached directly to the side of the subwall away from the substrate. Since the phase retarder 400 is also provided on the sidewall 102, the adhesive configured to fix the light-transmitting scaling layer 600 may be more, and the maximum thickness of the adhesive may be greater than the thickness of the light-transmitting sealing layer 600, to ensure that the light-transmitting sealing layer 600 can be fixed to the sidewall 102 by the adhesive to ensure the sealing effect on the frame.

In a particular embodiment, only the two opposite edges in the phase retarder 400 may also be fixed to the two opposite subwalls in the sidewall 102, respectively. For example, for the laser device 10 shown in FIG. 11, only the left and right edges in the phase retarder 400 may be fixed to the left and right subwalls, respectively, in the sidewall 102, while the edge toward the top is not fixed to the sidewall 102.

In another example, the phase retarder layer 400 is disposed in the frame surrounded by the sidewall 102. The inner surfaces of at least two opposing subwalls in the sidewall 102 have tabs, and two opposing edges in the phase retarder 400 are each attached to a side of the tabs on those two subwalls away from the substrate 101.

FIG. 13 is a schematic diagram of the structure of yet another laser device provided by embodiments of the present application. As shown in FIG. 13, the inner surfaces of the two subwalls facing each other in the sidewall 102 have tabs T, and the two edges facing each other in the phase retarder 400 are respectively fixed with the side of the tabs T to the two subwalls away from the substrate 101. The two sub-walls are opposite to each other in the row direction of the first type light emitting chip, and it is necessary to ensure that the positive projection of the phase retarder 400 on the substrate 101 covers only the first type light emitting chip and does not cover the second type light emitting chip. The two sub-walls are two sub-walls of the side wall 102 in the y-direction, i.e., the left sub-wall and the right sub-wall in FIG. 13. The left edge of the phase retarder 400 is attached to the tab T on the left subwall in the sidewall 102, and the right edge of the phase retarder 400 is attached to the tab T on the right subwall in the sidewall 102.

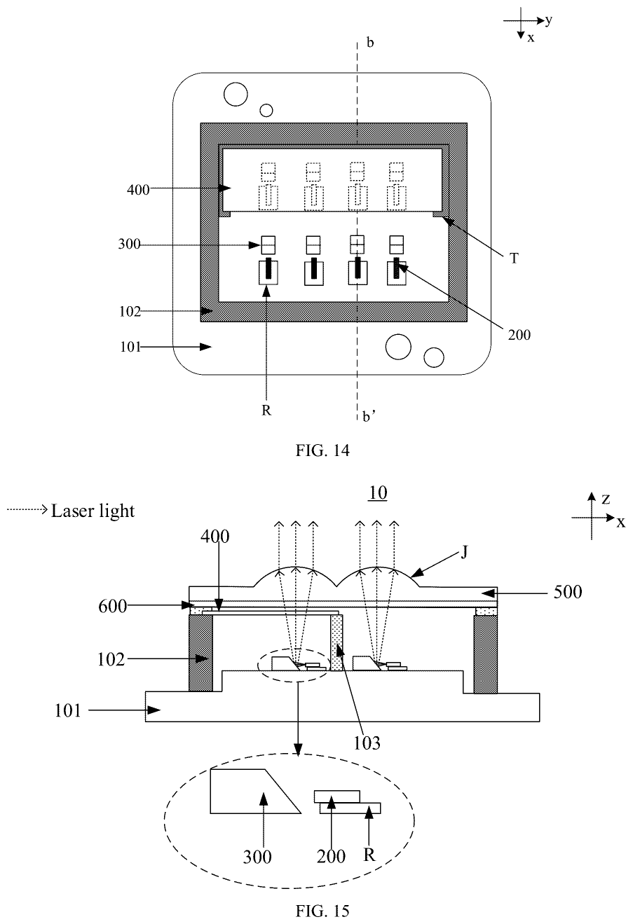

FIG. 14 is a schematic diagram of a structure of a laser device provided in another embodiment of the present application. In the sidewall 102, in addition to the inner surfaces of the two opposing subwalls having the tabs T, the inner surfaces of the subwalls between the two subwalls and near the first type light emitting chip also have the tabs T. As shown in FIG. 14, the inner surfaces of the subwalls on the upper side of the sidewall 102 also have the tabs T. The three edges of the phase retarder piece 400 are fixed with the tabs T to each of the three subwalls on the side away from the substrate 101. In this way, the area of fixation of the phase retarder piece 400 with the tabs T is larger, and the fixation of the phase retarder piece 400 is more solid.

In a specific implementation, the tabs T in this embodiment of the present application may be integrally formed with the sidewalls 102, such as a piece of layered metal that may be ground or etched to form the sidewalls 102 with the tabs T. In a specific implementation, the surfaces of the tabs T away from the substrate 101 are all flat. In a specific implementation, the length of the tabs on each sidewall may be equal to the length of the sidewall or may be less than the length of the sidewall. In a specific embodiment, the tabs on each subwall may also include a plurality of small, independent tabs arranged along the length of the subwall. The length direction of the subwall is the direction of extension of the parallel substrate 101 of the subwall.

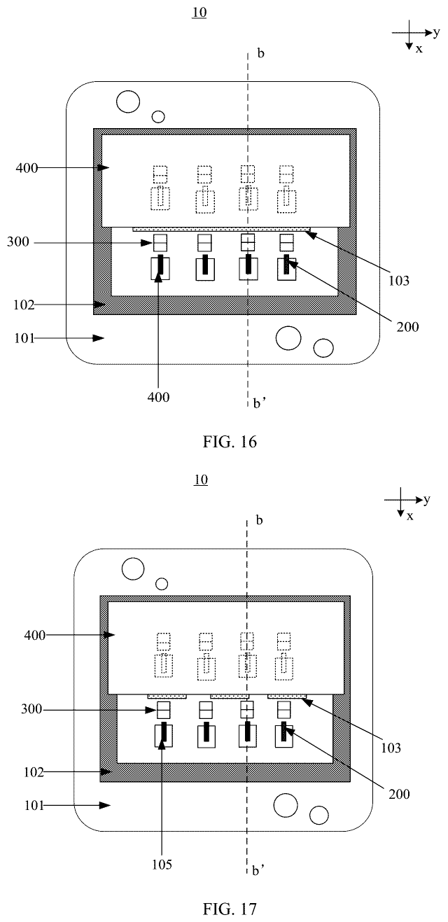

In a second optional arrangement, FIG. 15 is a schematic view of the structure of another laser device provided by another embodiment of the present application, FIG. 16 is a schematic view of the structure of yet another laser device provided by another embodiment of the present application, and FIG. 17 is a schematic view of the structure of yet another laser device provided by another embodiment of the present application. FIG. 16 and FIG. 17 may be top views of the laser device shown in FIG. 15, and FIG. 15 may be a schematic view of a cross-section b-b′ in the laser device shown in FIG. 16 or FIG. 17. As shown in FIGS. 15 through 17, in addition to FIGS. 10 and 11, the laser device 10 may further include at least one bracket 103, wherein the bracket 103 may be disposed on the substrate 101 and surrounded by the sidewalls 102, and one edge (e.g., a first edge) of the phase retarder 400 may be supported by the bracket 103, e.g., attached to the side of the bracket 103 away from the substrate 101. The remaining three edges may remain supported by the sidewall 102.

In a particular embodiment, as shown in FIG. 16, the at least one bracket 103 may be a strip-plate bracket, and a support surface of the bracket 103 may extend in the y-direction. A length of the holder 103 may be greater than a total row length of the plurality of first type light emitting chips. Both ends of the holder 103 may be spaced from the sidewall 102 (as shown in FIG. 16), or both ends of the holder 103 may be in contact with the sidewall 102, which is not shown in this application embodiment. When only one holder 103 is provided in the laser device 10, the mounting process of this holder 103 is simpler and facilitates the preparation of the laser device 10.

In an optional mounting method of the holder 103, the holder 103 may be underside mounted on the substrate 101 to realize the mounting of the holder 103. In the case where the bracket 103 is fixed to the substrate 101, the bracket 103 may be integrally molded with the substrate 101; or the bracket 103 and the substrate 101 may be two separate structures welded together to realize the fixing of the bracket 103. In another optional fixing of the bracket 103, both ends of the bracket 103 are in contact with the sidewall 102, which is fixed to the sidewall 102 to achieve fixing of the bracket 103. In a specific implementation, when both ends of the bracket 103 are fixed to the sidewall 102, the bracket 103 may not be fixed to the substrate 101, such as when there is a gap between the bracket 103 and the substrate 101. In a specific implementation, the bracket 103 may be integrally molded with the sidewall 102; or the bracket 103 and the sidewall 102 may be two separate structures that are welded together to achieve fixation of the bracket 103.

In a further specific embodiment, as shown in FIG. 17, the at least one bracket 103 may also include a separate plurality of brackets that may be arranged in rows along the y-direction, and the plurality of brackets 103 collectively support the first edge of the phase retarder 400. The plurality of brackets also corresponds to a division of one of the plate-shaped brackets of FIG. 16 into a plurality of sections, which is achieved by spacing adjacent sections. In a particular embodiment, the two brackets 103 located at the two ends may be spaced apart from the sidewall 102 (as shown in FIG. 17), or both of the two brackets 103 at the two ends may also be in contact with the sidewall 102 in a manner not shown in embodiments of the present application. In this approach, the plurality of brackets 103 may be underside attached to the substrate 101 to secure the plurality of brackets 103.

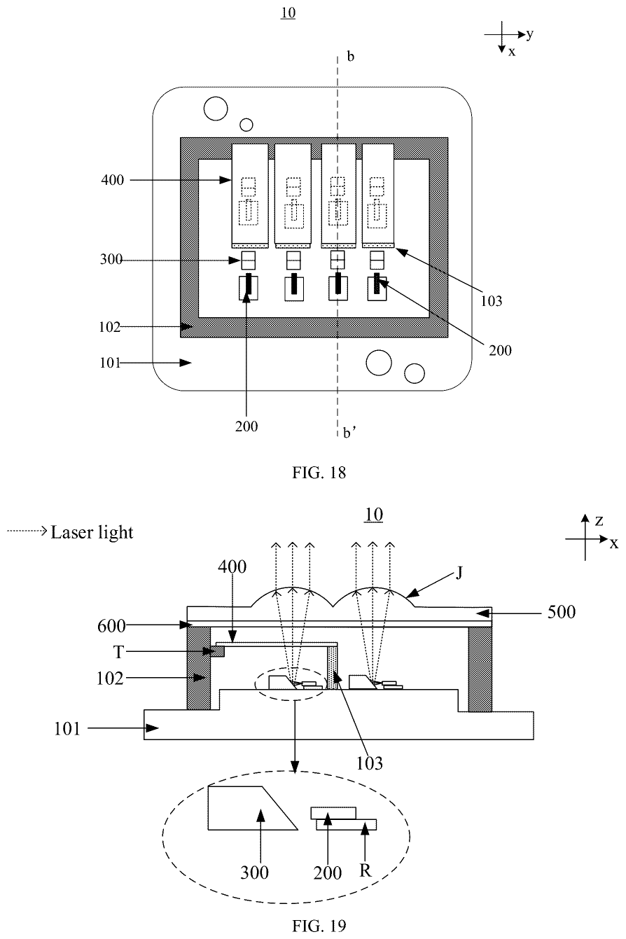

It is noted that FIG. 16 and FIG. 17 are schematically illustrated with an example of the laser device 10 including only one phase retarder 400. In a specific implementation, FIG. 18 is a schematic diagram of a structure of a laser device provided in a further embodiment of the present application. As shown in FIG. 18, the laser device 10 may also include a plurality of phase retarder tablets 400, wherein a positive projection of each phase retarder tablet 400 on the substrate 101 may cover a portion of the first type light emitting chips in the laser device 10 to ensure that the positive projections of the plurality of phase retarder tablets 400 on the substrate 101 collectively cover all of the first type light emitting chips in the laser device 10. Each phase retarder 400 may cover one first type light emitting chip and its corresponding reflective prism 300 (as shown in FIG. 18), or it may also cover two or more first type light emitting chips and their corresponding reflective prisms 300, and the embodiments of this application are not limited. Exemplarily, the plurality of phase retarder chips 400 may be arranged along the y-direction as shown in FIG. 18. A first edge of each phase retarder 400 is attached to the bracket 103, a second edge is attached to the sidewall, and the first edge is opposite the second edge. In a particular implementation, the number of phase retarders 400 is the same as the number of brackets 103, and the first edge of each phase retarder 400 may be supported by only one bracket 103.

In a third optional arrangement, the laser device 10 includes at least one bracket 103 disposed on the substrate 101 and surrounded by the sidewall 102, wherein the sidewall 102 has a tab T on an inner surface, and the phase retarders 400 are supported by the at least one bracket 103 together with the tab T. In a specific implementation, the tab T may be integrally formed with the sidewall 102, such as a piece of sheet material that may be ground or etched to form the sidewall 102 with the tab T. In a specific implementation, the surface of the bracket 103 facing away from the substrate 101 and the surface of the tab T facing away from the substrate 101 are both flat and both parallel to the plate surface of the substrate 101. The two surfaces may be at equal distances from the substrate 101. The phase retarder 400 is attached to the surface of this bracket 103 away from the substrate 101, and is attached to the surface of this tab T away from the substrate 101.

The at least one bracket 103 may be a strip plate bracket or may comprise a plurality of brackets 103. For the optional realization of the at least one bracket 103 and the fixing method, reference may be made to the relevant introduction in the second setting method of the phase retarder layer 400 described above, and the embodiments of the present application will not be repeated herein. The number of phase retarders 400 may be one or a plurality. For the method of setting the plurality of phase retarders 400, reference may be made to the relevant introduction to FIG. 18 in the second optional setting method described above. The at least one holder 103 is only one holder and the number of phase retarders 400 is, for example, 1 in this third optional setting method. The sidewall 102 in the laser apparatus 10 is surrounded by a plurality of subwalls. The embodiment of the present application is also presented as an example in which the front projection of the sidewall 102 on the substrate 101 is substantially rectangular. The sidewall 102 is enclosed by four sub-walls, namely a first sub-wall, a second sub-wall, a third sub-wall, and a fourth sub-wall, and the first sub-wall is opposite the fourth sub-wall, the second sub-wall is opposite the third sub-wall, and the second sub-wall and the third sub-wall are both adjacent to the first sub-wall.

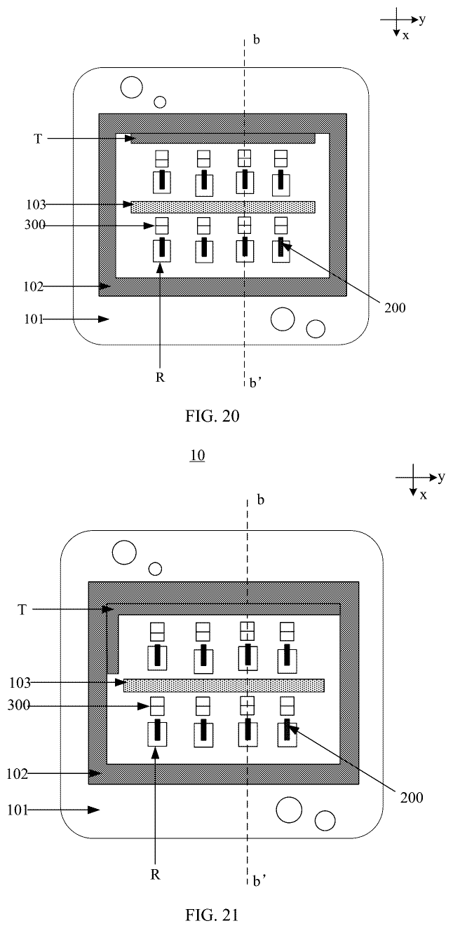

In a first example, FIG. 19 is a schematic diagram of the structure of another laser device provided by a further embodiment of the present application, FIG. 20 is a schematic diagram of the structure of yet another laser device provided by a further embodiment of the present application, FIG. 20 is a top view of the laser device shown in FIG. 19, and FIG. 19 is a schematic diagram of a cross-section b-b′ in the laser device shown in FIG. 20. As shown in FIGS. 19 and 20, the inner surface of the first subwall has tabs T. The tabs T on the inner surface of the sidewall 102 may be located only on the first subwall. A light emitting chip of a first type in the laser device 10 may be disposed between this tab T and the holder 103. A first edge of the phase retarder 400 is fixed to the side of the holder 103 away from the substrate 101, and a second edge of the phase retarder 400 is fixed to the side of the tab T away from the substrate 101. The first edge is opposite to the second edge, such that the first edge and the second edge are two edges of the phase retarder 400 that are opposite in the y-direction. In such an example, the phase retarder 400 is fixed in position by fixing the two opposite edges therein, and the phase retarder 400 is fixed in position.

In a particular embodiment, the tab T may be a strip tab. The length of the tab T on the first subwall may be equal to the length of that first subwall (e.g., in the x-direction), or the length of the tab T may be less than the length of the first subwall (as shown in FIG. 20), and the embodiments of the present application are not limited. The one strip-like tab is easier to fabricate. In a particular embodiment, the tab T on the first subwall may also include a plurality of independent small tabs arranged along the x-direction, and such an approach is not illustrated in this application embodiment. In this approach, if only one phase retarder 400 is included in the laser device 10, the second edge of the phase retarder 400 is simultaneously fixed to the surface of the plurality of small tabs away from the substrate 101. In a particular implementation, the distance between any two adjacent small tabs may be the same. When the laser device 10 includes a plurality of phase retarder tabs 400, the second edge of each phase retarder tab 400 may be fixed to a surface of a small tab away from the substrate 101, or may be fixed to a surface of the plurality of small tabs away from the substrate 101. In a particular implementation, the number of phase retarders 400, the number of small tabs on the first subwall, the number of brackets 103, and the number of first type light emitting chips may be the same, wherein each phase retarder 400 is supported by one small tab and one bracket 103 and covers one first type light emitting chip.

The embodiments of the present application do not limit the specific way of setting the tabs T on the first subwall, the number and shape, etc., but only ensure that the edges of the phase retarders 400 do not fall off after being fixed with the tabs.

In a second example, FIG. 21 is a schematic diagram of the structure of yet another laser device provided in a further embodiment of the present application, wherein the phase retarder 400 and the light-transmitting sealing layer 600 in the laser device are not shown in FIG. 21. As shown in FIG. 21, the inner surfaces of the first subwall and the second subwall in the sidewall 102 have tabs, i.e., tabs T on the inner surfaces of the sidewall 102 may be disposed on the first subwall and the second subwall. Only one phase retarder 400 may be included in the laser device 10, wherein a first edge of the phase retarder 400 is attached to a surface of the holder 103 away from the substrate 101, a second edge is attached to a tab on the first subwall away from the surface of the substrate 101, and a third edge is attached to a tab on the second subwall away from the surface of the substrate 101. In this manner, the phase retarder 400 is fixed in position by the fixation of three of the edges. In a particular embodiment, the laser device 10 may also include a plurality of phase retarders, wherein a third edge of the phase retarder 400 closest to the second subwall of the plurality of phase retarders 400 is fixed to the tab on the second subwall, and the other phase retarders 400 are fixed by only two of the edges. The realization of the tab on the second subwall may be the same as the realization of the tab on the first subwall, e.g., the tab may also be a strip tab or include a plurality of independent small tabs arranged along the x-direction, which may be referred to in the relevant introduction in the first example above and will not be further elaborated in the embodiments of the present application.

Thus, in a specific implementation, the length of the tab on the second subwall (i.e., the length in the x-direction) may be less than the total length of the second subwall, and only half of the area of the second subwall has a tab, and only the phase retardation chip 400 needs to be provided on which the tab can cover the first type light emitting chip and its corresponding reflective prism 300. In a particular embodiment, the length of the tab on the second sub-wall (i.e., the length in the x-direction) may also be equal to the overall length of the second sub-wall.

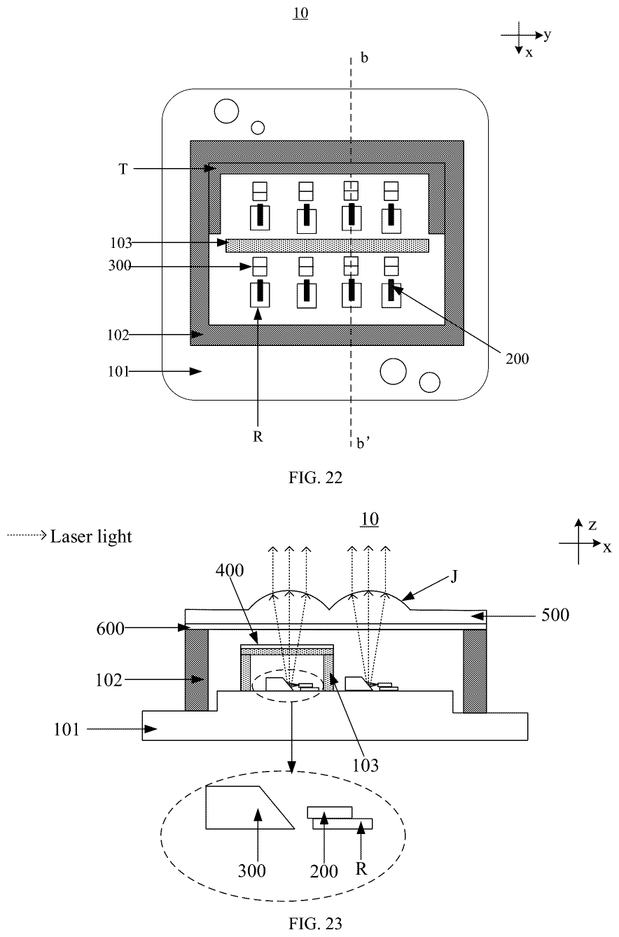

In a third example, FIG. 22 is a schematic diagram of a structure of a laser device provided in yet another embodiment of the present application, wherein the phase retarder 400 and the light-transmitting sealing layer 600 in the laser device are not shown in FIG. 22. As shown in FIG. 22, the inner surfaces of the first subwall, the second subwall, and the third subwall in the sidewall 102 have tabs, i.e., tabs T on the inner surfaces of the sidewall 102 may be disposed on the first subwall, the second subwall, and the third subwall. Only one phase retarder 400 may be included in the laser device 10, wherein a first edge of the phase retarder 400 is attached to a surface of the holder 103 away from the substrate 101, a second edge is attached to a tab on the first subwall away from the surface of the substrate 101, a third edge is attached to a tab on the second subwall away from the surface of the substrate 101, and a fourth edge is attached to a tab on the third subwall away from the surface of the substrate 101. In this manner, the phase retarder 400 is fixed in position by the fixation of four of the edges. In a particular embodiment, the laser device 10 may also include a plurality of phase retarders, wherein the plurality of phase retarders 400 may have a third edge of the phase retarder 400 closest to the second subwall fixed to the tabs on the second subwall, a fourth edge of the phase retarder 400 closest to the third subwall fixed to the tabs on the second subwall, and the remaining phase retarders 400 fixed by only two of the edges.

The implementation of the tab on the third subwall may be the same as the implementation of the tab on the first subwall and the second subwall, e.g., the tab may also be a strip tab or include a plurality of small independent tabs arranged along the x-direction, as described above with respect to the first example and the second example and will not be further detailed in the embodiments of the present application.

In a particular embodiment, each of the four subwalls of the sidewall 102 has a tab, which may be annular, and the length of the tab on each subwall may be equal to the length of the subwall. A positive projection of the tabs on the substrate 101 may enclose all of the light emitting chips 200 and their corresponding reflective prisms 300. In this way, the generality of the sub-wall 102 can be higher, and the first type light emitting chips in the laser device using the sub-wall 102 can be set with higher flexibility, and there is no need to restrict the first type light emitting chips to be set only at a certain position or in a certain relative relationship to the sub-wall 102, so that the light emitting chips can be set with higher flexibility. The placement flexibility of the light emitting chip is high.

Exemplarily, the first type light emitting chips and the second type light emitting chips can be arbitrarily arranged on the substrate 101, and it is only necessary to ensure that each of the first type light emitting chips and their corresponding reflective prisms 300 are located near the sidewalls 102, and thus it is only necessary to provide a bracket 103 on the rear side (i.e, (i.e., the side opposite to the light output side) of the first type light emitting chips, so that the bracket 103 and the tabs on the sidewalls 102 can be configured to support the phase delay chips 400 such that the phase delay chips 400 cover the first type light emitting chips and their corresponding reflective prisms 300.

It is to be noted that the structure, forming method, setting method, and fixing method with the phase retarder 400 of the tabs on the sub-wall in the third optional setting method and the tabs on the sub-wall in the first optional setting method may be the same, and the respective descriptions may be cross-referenced, and the embodiments of the present application are not limited.

In a fourth optional setup, the laser device 10 may include at least one bracket 103, the phase retarder 400 is supported only by the bracket 103, and the edges of the phase retarder 400 are fixed only to a surface of the bracket 103 away from the substrate 101. In this arrangement, the inner surface of the sidewall 102 may not have a tab or may still have a tab.

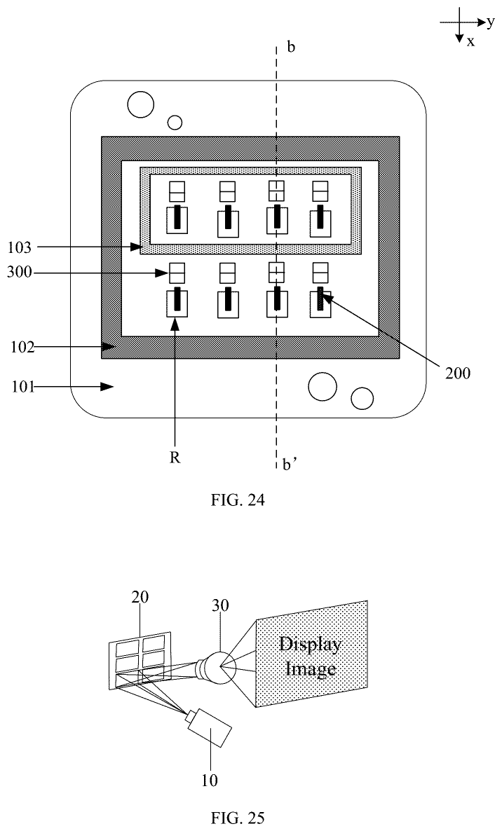

FIG. 23 is a schematic view of the structure of another laser device provided by yet another embodiment of the present application, and FIG. 24 is a schematic view of the structure of another laser device provided by yet another embodiment of the present application. FIG. 24 may be a top view of the laser device shown in FIG. 23, and FIG. 23 may be a schematic view of the cross-section b-b′ in the laser device shown in FIG. 24. As shown in FIGS. 23 and 24, each holder 103 includes a rectangular frame and four support feet disposed at each of the four corners of the rectangular frame, and a positive projection of each holder 103 on the substrate 101 may enclose at least one first type light emitting chip and its corresponding reflective prism 300. FIG. 24 illustrates the laser device 10 with respect to the laser device 10 including only one holder 103, and a positive projection of the holder 103 on the substrate 101 enclosing all of the first type light emitting chips and their corresponding reflective prisms 300 in the laser device 10 as an example. In a specific implementation, the laser device 10 may also include a plurality of holders 103, each of which encloses a portion of the first type light emitting chips in a positive projection on the substrate 101.

In a specific implementation, each holder 103 may have a tubular shape, and each holder 103 may be surrounded by four solid plates. In a specific implementation, each holder 103 may also be enclosed by three solid plates, in which case the holder 103 half encloses at least one first type light emitting chip and its corresponding reflective prism 300. In a specific implementation, the plurality of holders 103 in the laser device 10 may also be distributed on opposite sides of the plurality of first type light emitting chips and their corresponding reflective prisms 300, in which case the holder 103's structure can be referred to the description of the holder 103 in the three optional setting methods described above. In a particular embodiment, the holder 103 may also include four independent plate-like holders disposed around the at least one first type light emitting chip and its corresponding reflective prism 300. In this fourth optional arrangement, the manner in which the phase retarder 400 is provided on this holder 103 may be related to the manner in which the phase retarder 400 is provided on the sidewall 102 and the holder 103 in the three aforementioned optional arrangements, which will not be repeated in the embodiments of this application.

It should be noted that in the first three optional setting methods, they are all based on the example that the plurality of first type light emitting chips and the plurality of second type light emitting chips are set up in separate areas in the laser device 10, and the at least one holder 103 in the laser device 10 is located between the plurality of first type light emitting chips and the plurality of second type light emitting chips.

In a particular implementation, the material of the substrate 101 in embodiments of the present application may include a metal. The material may include copper, such as oxygen-free copper, or the material may also include other metals, such as aluminum or iron. It should be noted that the light emitting chip 200 generates more heat when emitting laser light, and copper has a higher thermal conductivity. In the embodiment of the present application, the material of the substrate 101 is copper to ensure that the heat generated by the light emitting chip 200 provided on the substrate 101 during operation can be quickly conducted through the substrate 101 and then quickly emitted to avoid damage to the light emitting chip due to heat accumulation. In a specific implementation, the material of the substrate 101 may also be one or more of aluminum, aluminum nitride, and silicon carbide. In a specific implementation, the material of the substrate 101 may also include ceramic.

In a specific implementation, the material of the bracket 103 may include metal or ceramic. Exemplarily, the material of the bracket 103 may be the same as the material of the substrate 101, and the bracket 103 may be integrally molded with the substrate 101 or fixed to the substrate 101 by brazing. The material of the bracket 103 may also be the same as the material of the sidewall 102, and the bracket 103 may be integrally molded with the sidewall 102, or fixed to the sidewall 102 by brazing or taping.

In embodiments of the present application, an edge region of a side surface of the phase retarder 400 may be prepositioned with a solder. The solder may be, for example, a gold-tin solder, and the material of the solder may include gold and tin. In a particular implementation, the solder may cover at least two edge regions of the phase retarder 400, for example, may cover four edge regions. Each edge region of the solder may be continuous, or only a few spaced blocks of solder may be set, just to ensure that based on the solder the phase retarder 400 can be securely fixed, the present application embodiments for the phase retarder in the coverage of the solder and the specific location of the position is not limited.

For example, in a particular implementation in which the phase retarder 400 is supported by the tabs T on the sidewall 102 in conjunction with the clip 103, in securing the phase retarder 400, the edges of the phase retarder 400 may first be lapped over the tabs T on the sidewall 102 and the clip 103. The edge region of the phase retarder 400 is then heated to melt the solder on the phase retarder 400. The molten solder can then be cooled to solidify the solder to secure the phase retarder piece 400 to the sidewall 102 and bracket 103. In a laser device in which the phase retarder piece 400 is otherwise supported, the phase retarder piece 400 is secured in the same manner.

In a particular implementation, the material of the phase retarder piece 400 may include sapphire. The sapphire has a higher coefficient of expansion that matches the ceramic sidewall, which allows for a better connection between the phase retarder 400 and the sidewall 102 and reduces cracking of the ceramic due to stress. In a specific implementation, the area of the phase retarder 400 can be as small as possible, just enough to ensure that the laser light emitted from the first light emitting chip can all be injected into the phase retarder 400, thereby reducing the preparation cost of the laser device 10.

In a particular embodiment, the material of the light-transmitting sealing layer 600 may be glass, sapphire, quartz, or Bk7 model corona glass and the like. The manner in which the light-transmitting sealing layer 600 is constructed in the laser device 10 is described below in conjunction with the accompanying drawings.

Referring back to FIGS. 10, 7, 11 and 15, the edges of the light-transmitting sealing layer 600 may be directly attached to the surface of the sidewall 102 away from the substrate 101, and thus the light-transmitting sealing layer 600 may enclose an airtight space with the substrate 101 and the sidewall 102. For example, a sealing light-transmitting layer 600 may be directly attached to the edge of the light-transmitting sealing layer 600 with the surface of the sidewall 102 away from the substrate 101 using a sealant. Alternatively, the light-transmitting sealing layer 600 may be pre-set with a solder at the edge of the light-transmitting sealing layer 600, which in turn melts the solder and then sets the light-transmitting sealing layer 600 on the side of the sidewall 102 away from the substrate 101 to fix the light-transmitting sealing layer 600 to the sidewall 102. When the solder is a gold-tin solder.

In a specific embodiment, with continued reference to FIGS. 10, 7, 11, and 15, the laser device 10 may further include a collimating mirror group 500 that can collimate the incoming laser light so that the laser light is tuned to emit near-parallel light. The collimating mirror group 500 is located on a side of the light-transmitting sealing layer 600 that may be located away from the substrate 101. The collimating mirror group 500 may include a plurality of collimating lenses J that correspond one-to-one with a plurality of light emitting chip units 200 in the laser device 10. Each light emitting chip 200 emits a laser light to a corresponding reflecting prism 300, which reflects the incoming laser light toward the light-transmitting sealing layer 600, which, after transmission of the light-transmitting sealing layer 600, may be directed to the collimating lens J corresponding to that light emitting chip 200. The collimating lens J can collimate the incoming laser light and then shoot it out, thereby realizing the light emission of the laser device 10.

The plurality of collimating lenses in the collimating mirror group 500 may be integrally molded. The side of the collimating mirror group 500 away from the substrate 101 may have a plurality of convex curved surfaces curved toward the side away from the substrate 101. The portion of the collimated mirror assembly 500 in which each of the convex curved surfaces is located may serve as a collimating lens J, and thus the collimated mirror assembly 500 may be considered to include a plurality of collimating lenses J.

In summary, in the laser device provided in several embodiments of the present application, a phase retarder is provided in the laser device on a side of the light emitting chip away from the substrate, and a positive projection of the phase retarder on the substrate covers each of the first type light emitting chips and the corresponding reflecting prisms in the laser device and is located outside of each of the second type light emitting chips and the corresponding reflecting prisms in the laser device. In this way, the laser light emitted from the first type light emitting chip can be reflected on the corresponding reflecting prisms and then emitted after the phase retarder rotates the adjusted polarization direction by 90 degrees, while the polarization direction of the laser light emitted from the second type light emitting chip does not change. The laser light emitted from the first type light emitting chip is polarized in the same direction as the laser light emitted from the second type light emitting chip after the phase retarder, and the laser light emitted from the laser apparatus is polarized in the same direction. Therefore, the laser emitted from the laser device originating from different types of light emitting chips has a smaller difference in transmissive-reflective properties when transmitted in the subsequent optical components, and the laser emitted from the laser device has a smaller change in the ratio of the various colors of the laser light after passing through the subsequent optical components, so as to attenuate the color deviation of the projection image formed by the laser light and improve the display effect of the projection image.

In addition, with respect to the manner of fixing the phase retarder chip to the side wall of the laser device or the mount in the multiple examples described above, the area covered by the positive projection of the phase retarder chip on the substrate may also correspond to a portion of the first type light emitting chip and the corresponding reflecting prism, thereby changing the direction of polarization of the laser beam emitted from only a portion of the first type light emitting chip, and, in the specific embodiment, the phase retarder chip is a phase retarder chip of the second type, the phase retarder chip is a phase retarder chip of the third type, the phase retarder chip is a phase retarder chip of the fourth type, and the phase retarder chip is a phase retarder chip of the fifth type, the phase retardation chip is a half-wave chip corresponding to half of the number of the first type light emitting chips, thereby changing the polarization direction of the laser beam emitted from only half of the first type light emitting chips, and the laser beam emitted from the other half of the number of the first type light emitting chips does not pass through the half-wave chip, thereby maintaining the original polarization direction. In the arrangement described above, the degree of difference in polarization direction from the second type light emitting chip is reduced by having two different polarization directions for the first type light emitting chip, and the laser beams having two different polarization directions for the same type of light emitting chip also contribute to reducing the degree of coherence.

Further, the phase retardation chips may also correspond to a portion of the first type light emitting chips and a portion of the second type light emitting chips, respectively, and are also specifically selected to be both 50%, wherein, among the plurality of first type light emitting chips and the plurality of second type light emitting chips, the polarization direction of half of the laser beams of each of the plurality of first type light emitting chips and the polarization direction of the laser beams of each of the plurality of second type light emitting chips is changed, and the polarization direction of the laser beams of the plurality of second type light emitting chips of each of the plurality of second type light emitting chips is maintained in the original polarization direction. As a result, the first type light emitting chip and the second type light emitting chip have two different polarization directions, and the degree of difference in the polarization directions is improved, and the laser beams having two different polarization directions for the same type of light emitting chip also contribute to a reduction in the degree of coherence.

Another aspect of the embodiments of the present application provides a laser projection apparatus, and FIG. 25 shows a schematic diagram of a structure of the laser projection apparatus provided by the embodiments of the present application.

As shown in FIG. 25, an embodiment of the present application provides a laser projection apparatus including: any of the above-described laser apparatus light sources 10, an optical valve modulation component 20, and a projection lens 30.

In the package structure of the laser device light source 10, a phase retarder is provided on a prism on the light output side of the laser light emitting chip or at least in the light output path in the reflection direction of the prism, so that the laser beam emitted from one type of the light emitting chip passes through the phase retarder in the same polarization direction as that of the laser beam emitted from another type of the light emitting chip, thereby avoiding color problems caused by different polarization states. Different polarization states can be avoided because of the color problems caused by different polarization states.

Furthermore, when the phase retarder chip is provided in a portion of the outgoing beam optical path of the two types of light emitting chips, it is possible to have two polarization states of the same color of light existing in the outgoing laser beam obtained from the laser device, so that on the one hand, it is possible to reduce a difference state in which the two types of light emitting chips have polarization directions that are completely orthogonal to each other, and, at the same time, it is possible to reduce a degree of coherence of the light of the same color.

The light valve modulating component 20 is located on the light exit side of the laser device 10, and the light valve modulating component 20 is configured to reflect the incident light after modulation. In an embodiment of the present application, the light valve modulation component 20 may use a digital micromirror device (DMD), which is a reflective light valve device, and the surface of the DMD includes thousands of tiny mirrors, and the modulation of the light can be realized by controlling the flip angle of the tiny mirrors and the duty cycle.

The projection lens 30 is disposed in the reflected light path of the light valve modulating component 20, and the projection lens 30 is configured to image the light exiting from the light valve modulating component.

Although preferred embodiments of the present application have been described, those skilled in the art may make additional changes and modifications to these embodiments once the basic inventive concepts are known. Therefore, the appended claims are intended to be construed to include the preferred embodiments as well as all changes and modifications within the scope of this application.

Of course, those skilled in the art may make various modifications and variations of the present application without departing from the spirit and scope of the present application. Thus, to the extent that such modifications and variations of the present application fall within the scope of the claims of the present application and their technical equivalents, the present application is intended to encompass such modifications and variations.

1. A laser device, comprising:
at least one frame, each of the at least one frame comprising a substrate and an annular sidewall disposed on the substrate;
a sealing light-transmitting layer connected to the annular sidewall, the substrate, the annular sidewall and the sealing light-transmitting layer forming a sealed accommodating space;
a plurality of light emitting chips mounted on the substrate of the frame, the light emitting chips comprising at least one first type light emitting chip and at least one second type light emitting chip, a polarization direction of laser beam emitted from the first type light emitting chip being different from a polarization direction of laser beam emitted from the second type light emitting chip;
at least one prism, each of the at least one prism corresponding to at least one of the light emitting chips, each of the at least one prism being configured to receive a laser beam from a corresponding light emitting chip and to reflect the laser beam toward a light emitting direction of the laser device; and
a phase retarder, disposed within the accommodating space and parallel to the substrate, wherein a laser beam from at least a part of the light emitting chips passes through the phase retarder to change a polarization direction before being transmit to the sealing light-transmitting layer.

2. The laser device according to claim 1, wherein each of the at least one prism comprises: a top surface, a bottom surface and a reflective surface, wherein the bottom surface of the prism is mounted on the bottom plate, the top surface is a surface opposite to the bottom surface, the reflective surface is a slope surface facing to the at least one of the light emitting chips and is configured to reflect a laser beam from the at least one of the light emitting chips, and the phase retarder is at an edge, close to the reflective surface, of the top surface of each of the at least one prism and extends beyond the edge of the top surface.

3. The laser device according to claim 2, wherein the plurality of light emitting chips is arranged in a row along a set direction, the row comprising at least one of the first type light emitting chip and at least one of the second type light emitting chip, and each of the at least one prism is provided with the phase retarder on one of a region corresponding to the first type light emitting chip and a region corresponding to the second type light emitting chip.

4. The laser device according to claim 2, wherein the at least one first type light emitting chip is arranged in at least one first type light emitting chip row and the at least one second type light emitting chip is arranged in at least one second type light emitting chip row; each of the at least one prism is provided with the phase retarder which is in a transmission path of laser beams from the at least one first type light emitting chip row or the at least one second type light emitting chip row; and
wherein the at least one first type light emitting chip comprises at least two light emitting chips which emit laser beams having two different colors, and the at least one second type light emitting chip emits a laser beam having one color.

5. The laser device according to claim 1, wherein the at least one first type light emitting chip comprises at least two light emitting chips which emit blue and green laser beams, and the at least one second type light emitting chip emits a red laser beam.

6. The laser device according to claim 5, wherein the at least one prism is provided with the phase retarder in one of the following ways:
the phase retarder is in a transmission path of a laser beam from each of light emitting chips emitting red laser beams, and the phase retarder is not in a transmission path of a laser beam from each of light emitting chips emitting blue laser beams and light emitting chips emitting green laser beams;
the phase retarder is in a transmission path of a laser beam from each of a part of light emitting chips emitting red laser beams, and the phase retarder is not in a transmission path of a laser beam from each of light emitting chips emitting blue laser beams and light emitting chips emitting green laser beams; and
the phase retarder is in a transmission path of a laser beam from each of a part of light emitting chips emitting red laser beams, a part of light emitting chips emitting blue laser beams, and a part of light emitting chips emitting green laser beams.

7. The laser device according to claim 3, wherein each of the at least one prism is a strip prism extending in a row direction of laser chip units, each of the at least one prism corresponding to at least one row of light emitting chips, and wherein the phase retarder is provided on the top surface of each of the at least one prism and is configured to transmit laser beams which come from the at least one row of light emitting chips and are reflected by a prism corresponding to the at least one row of light emitting chips.

8. The laser device according to claim 7, wherein the reflective surface comprises: a first reflective surface and a second reflective surface, the first reflective surface and the second reflective surface being disposed symmetrically with respect to the top surface; the first type light emitting chip row being disposed on a side opposite to the first reflective surface of the prism; the second type light emitting chip row being disposed on a side opposite to the second reflective surface of the prism; and the phase retarder is disposed at an edge, close to one of the first reflective surface and the second reflective surface, of the top surface of the prism.

9. The laser device according to claim 1, wherein the sidewall has at least one tab facing an interior of the accommodating space, the phase retarder being fixed to the tab on the sidewall; the sidewall being made of a material comprising ceramic.

10. The laser device according to claim 1, wherein the laser device further comprises at least one bracket disposed on the substrate and surrounded by the sidewall, the bracket is of a material comprising one of ceramic and copper, and a connecting way between the bracket and the substrate is one of integrated molding and welding; and
the phase retarder is disposed on the at least one bracket and the phase retarder is fixed to the bracket by soldering.

11. The laser device according to claim 1, wherein the phase retarder is fixed to a side of the at least one bracket away from the substrate, and the phase retarder is further fixed to the sidewall.

12. The laser device according to claim 1, wherein the laser device further comprises:
a plurality of collimating lenses, each of the collimating lenses corresponding to a plurality of the light emitting chips;
wherein the plurality of collimating lenses is fixed to the substrate and between a corresponding plurality of light emitting chips and a corresponding prism.

13. The laser device according to claim 4, wherein each of the at least one prism is a strip prism extending in a row direction of laser chip units, each of the at least one prism corresponding to at least one row of light emitting chips, and wherein the phase retarder is provided on the top surface of each of the at least one prism and is configured to transmit laser beams which come from the at least one row of light emitting chips and are reflected by a prism corresponding to the at least one row of light emitting chips.

14. The laser device according to claim 13, wherein the reflective surface comprises: a first reflective surface and a second reflective surface, the first reflective surface and the second reflective surface being disposed symmetrically with respect to the top surface; the first type light emitting chip row being disposed on a side opposite to the first reflective surface of the prism; the second type light emitting chip row being disposed on a side opposite to the second reflective surface of the prism; and the phase retarder is disposed at an edge, close to one of the first reflective surface and the second reflective surface, of the top surface of the prism.

15. A laser projection equipment comprising:
a laser device;
a light valve modulation member, located on the light emitting side of the laser device, the light valve modulation member being configured to modulate light from the laser device; and
a projection lens, located on the light emitting side of the light valve modulation member;
wherein laser device comprises:
a frame comprising a substrate and an annular sidewall disposed on the substrate;
a sealing light-transmitting layer connected to the annular sidewall, the substrate, the annular sidewall and the sealing light-transmitting layer forming a sealed accommodating space;
a plurality of light emitting chips mounted on the substrate of the frame, the light emitting chips comprising at least one first type light emitting chip and at least one second type light emitting chip, a polarization direction of laser beam emitted from the first type light emitting chip being different from a polarization direction of laser beam emitted from the second type light emitting chip;
at least one prism, each of the at least one prism corresponding to at least one of the light emitting chips, each of the at least one prism being configured to receive a laser beam from a corresponding light emitting chip and to reflect the laser beam toward a light emitting direction of the laser device; and
a phase retarder, disposed within the accommodating space and parallel to the substrate, wherein a laser beam from at least a part of the light emitting chips passes through the phase retarder to change a polarization direction before being transmit to the sealing light-transmitting layer.

16. The laser projection equipment according to claim 15, wherein each of the at least one prism comprises: a top surface, a bottom surface and a reflective surface, wherein the bottom surface of the prism is mounted on the bottom plate, the top surface is a surface opposite to the bottom surface, the reflective surface is a slope surface facing to the at least one of the light emitting chips and is configured to reflect a laser beam from the at least one of the light emitting chips, and the phase retarder is at an edge, close to the reflective surface, of the top surface of each of the at least one prism and extends beyond the edge of the top surface.

17. The laser projection equipment according to claim 16, wherein each of the light emitting chips is arranged in a row along a set direction, the row comprising at least one of the first type light emitting chip and at least one of the second type light emitting chip, and each of the at least one prism is provided with the phase retarder on one of a region corresponding to the first type light emitting chip and a region corresponding to the second type light emitting chip.

18. The laser projection equipment according to claim 16, wherein each of the at least one first type light emitting chip is arranged in at least one first type light emitting chip row and each of the at least one second type light emitting chip is arranged in at least one second type light emitting chip row; each of the at least one prism is provided with the phase retarder on one of a region corresponding to the at least one first type light emitting chip row and a region corresponding to the at least one second type light emitting chip row; and
wherein one of the first type light emitting chip and the second type light emitting chip emits laser beams having two colors and the other emits laser beams having one color.

19. The laser projection equipment according to claim 17, wherein each of the at least one prism is a strip prism extending in a row direction of laser chip units, each of the at least one prism corresponding to at least one row of light emitting chips, and wherein the phase retarder is provided on the top surface of each of the at least one prism and is configured to transmit laser beams which come from the at least one row of light emitting chips and are reflected by a prism corresponding to the at least one row of light emitting chips.

20. The laser projection equipment according to claim 19, wherein the reflective surface comprises: a first reflective surface and a second reflective surface, the first reflective surface and the second reflective surface being disposed symmetrically with respect to the top surface; the first type light emitting chip row being disposed on a side opposite to the first reflective surface of the prism; the second type light emitting chip row being disposed on a side opposite to the second reflective surface of the prism; and the phase retarder is disposed at an edge, close to one of the first reflective surface and the second reflective surface, of the top surface of the prism.
